(19) United States
(12) Patent Application Publication
(10) Pub. No.: US 2024/0235954 A1
(43) Pub. Date: Jul. 11, 2024

(54) MODEL LEARNING METHOD, MODEL LEARNING APPARATUS, AND STORAGE MEDIUM

(71) Applicants: Beijing Xiaomi Mobile Software Co., Ltd., Beijing (CN); (BEIJING UNIVERSITY OF POSTS AND TELECOMMUNICATIONS), Beijing (CN)

(72) Inventors: Qin MU, Beijing (CN); Wei HONG, Beijing (CN); Zhongyuan ZHAO, Beijing (CN); Yifan CAI, Beijing (CN)

(21) Appl. No.: 18/560,372

(22) PCT Filed: May 14, 2021
(86) PCT No.: PCT/CN2021/093927

§ 371 Date: Nov. 10, 2023

(51) Int. Cl. H04L 41/16; H04W 16/32

(52) U.S. Cl. CPC H04L 41/16; H04W 16/32

(57) ABSTRACT

A method for model learning, the method includes in response to reception of a model training request sent by an operation administration and maintenance (OAM) entity, sending the model training request to a first number of micro base stations, where a communication coverage range of the first number of micro base stations being within a communication coverage range of the macro base station.

### TECHNICAL FIELD

The disclosure relates to the technical field of wireless communication, in particular to a method and apparatus for model learning, and a storage medium.

### BACKGROUND

In communication technologies, in order to increase peak rate and improve spectral efficiency, a heterogeneous network technology is introduced. The heterogeneous network technology refers to a technology which distributes many micro base stations within a coverage range of a macro base station and forming a heterogeneous system with different types of covered nodes. As a geographical distance between an access point and served user equipment is reduced, a system throughput and an overall network efficiency can be effectively improved.

### SUMMARY

According to a first aspect of the disclosure, a method for model learning is provided, the model is performed by a macro base station, and includes:

sending a model training request to a first number of micro base stations in response to reception of a model training request sent by an operation administration and maintenance (OAM) entity, where a communication coverage range of the first number of micro base stations being within a communication coverage range of the macro base station.

According to a second aspect of the disclosure, a method for model learning is provided, the method is performed by a micro base station and includes:

receiving a model training request sent by a macro base station; and sending the model training request to a terminal, where the number of micro base stations receiving the model training request is a first number, and a communication coverage range of the first number of micro base stations is within a communication coverage range of the macro base station.

According to a third aspect of the disclosure, an apparatus for model learning is provided, including:

a processor; and a memory configured to store an instruction executable by the processor, the processor being configured to execute the method for model learning in the first aspect or in any implementation of the first aspect or execute the method for model learning in a second aspect or in any implementation of the second aspect.

According to a fourth aspect of the disclosure, a non-transitory computer-readable storage medium is provided, and an instruction in the storage medium, when executed by a processor of a mobile terminal, enables the mobile terminal to execute the method for model learning in the first aspect or in any implementation of the first aspect or execute the method for model learning in a second aspect or in any implementation of the second aspect.

It is to be understood that the above general description and the following detailed description are merely exemplary and explanatory instead of limiting the disclosure.

### BRIEF DESCRIPTION OF THE DRAWINGS

Accompanying drawings here, which are incorporated in and constitute a part of the specification, illustrate embodiments consistent with the disclosure and, together with the specification, serve to explain principles of the disclosure.

FIG. 1 is a schematic diagram of a scene architecture of a heterogeneous network of a method for model learning shown according to an example.

FIG. 2 is a flowchart of a method for model learning shown according to an example.

FIG. 3 is a flowchart of yet another method for model learning shown according to an example.

FIG. 4 is a flowchart of yet another method for model learning shown according to an example.

FIG. 5 is a flowchart of yet another method for model learning shown according to an example.

FIG. 6 is a flowchart of yet another method for model learning shown according to an example.

FIG. 7 is a flowchart of yet another method for model learning shown according to an example.

FIG. 8 is a flowchart of yet another method for model learning shown according to an example.

FIG. 9 is a flowchart of yet another method for model learning shown according to an example.

FIG. 10 is a flowchart of yet another method for model learning shown according to an example.

FIG. 11 is a flowchart of yet another method for model learning shown according to an example.

FIG. 12 is a flowchart of yet another method for model learning shown according to an example.

FIG. 13 is a flowchart of yet another method for model learning shown according to an example.

FIG. 14 is a flowchart of yet another method for model learning shown according to an example.

FIG. 15 is a flowchart of yet another method for model learning shown according to an example.

FIG. 16 is a flowchart of yet another method for model learning shown according to an example.

FIG. 17 is a flowchart of yet another method for model learning shown according to an example.

FIG. 18 is a flowchart of yet another method for model learning shown according to an example.

FIG. 19 is a main flowchart of a method for model learning shown according to an example.

FIG. 20 is a flowchart of federated learning of model reasoning in a method for model learning shown according to an example.

FIG. 21 is a flowchart of terminal switching processing in a method for model learning shown according to an example.

FIG. 22 is a flowchart of model reasoning of a method for model learning shown according to an example.

FIG. 23 is a principle diagram of a protocol and an interface for signaling and data transmission performed between a micro base station and a macro base station in a method for model learning shown according to an example.

FIG. 24 is a principle diagram of a protocol and an interface for signaling and data transmission performed between a micro base station and a terminal in a method for model learning shown according to an example.

FIG. 25 is a principle diagram of a protocol and an interface for terminal switching in a method for model learning shown according to an example.

FIG. 26 is a block diagram of an apparatus for model learning shown according to an example.

FIG. 27 is a block diagram of yet another apparatus for model learning shown according to an example.

FIG. 28 is a block diagram of an apparatus for model learning shown according to an example.

FIG. 29 is a block diagram of yet another apparatus for model learning shown according to an example.

### DETAILED DESCRIPTION

The examples will be described in detail here, and their instances are represented in the accompanying drawings. Unless otherwise indicated, when the following description refers to the accompanying drawings, the same number in the different accompanying drawings represents the same or similar elements. Implementations described in the following examples do not represent all implementations consistent with the disclosure. Rather, they are merely examples of an apparatus and method consistent with some aspects of the disclosure as detailed in appended claims.

The disclosure relates to the technical field of wireless communication, in particular to a method and apparatus for model learning, and a storage medium.

In communication technologies, in order to increase peak rate and improve spectral efficiency, a heterogeneous network technology is introduced. The heterogeneous network technology refers to a technology which distributes many micro base stations within a coverage range of a macro base station and forming a heterogeneous system with different types of covered nodes. As a geographical distance between an access point and served user equipment is reduced, a system throughput and an overall network efficiency can be effectively improved.

In another aspect, with development of an artificial intelligence technology, machine learning is applied to more and more fields, and federated learning is one of learning methods in machine learning. Federated learning refers to a method of machine learning by combining different participants (for example, terminals), and the different participants are in collaborative learning, which may effectively ensure information security during big data exchange, and protect terminal data and personal data privacy. Federated learning is applied to a multi-source heterogeneous network, and machine learning modeling of the multi-source heterogeneous network may be implemented, implementations of which may refer to the following embodiments.

A macro base station forwards a specific subscription demand of an operation administration and maintenance (OAM) entity to a terminal. The subscription demand of the OAM may also be called a model training request. The terminal reports a communication condition and a local data type feature to the macro base station. The macro base station performs task assignment according to information reported by the terminal and issues a model structure and hyper-parameter information to the terminal. The terminal performs local model training according to a task assigned by the macro base station, and after training is completed, the terminal sends a local learning model parameter to the macro base station. The macro base station performs federated averaging according to a local learning result of the terminal to obtain a global model. The macro base station checks whether the global learning model meets the subscription demand of the OAM, and if yes, the macro base station sends the obtained model to the OAM. If not, the terminal updates a local model according to a global learning result and then performs training by repeated iteration with the macro base station till an obtained global model meets the subscription demand of the OAM.

It may be seen from the above implementation that there are following defects in the related art.
1) The terminal is directly connected with the macro base station for performing data and signaling transmission, and as for a terminal at an edge of a coverage range of the macro base station, a geographical distance between the terminal and the macro base station is large, channel quality is poor, a data transmission rate is low, overall efficiency of a communication network is affected, and consequently, efficiency of a federated learning process is low.
2) The macro base station directly performs federated averaging on local training results of all terminals, in actual application, data structures of local training sets of the different terminals may be different, feasibility of directly performing federated averaging is low, poor model generalization capability may be caused, and model reliability and accuracy cannot be guaranteed.
3) Data interaction between the macro base station and the terminal needs to be performed through a core network or a data center, the terminal needs to upload training result data to the core network or the data center, then the macro base station requests data, federated learning by direct data transmission between the base station and the terminal is not supported, and efficiency of federated learning and a utilization rate of wireless network resources are reduced.
4) The terminal exits a connection to the macro base station, which means directly exiting the federated learning process without considering a processing flow of adding and connecting a new terminal, consequently, available training data in the federated learning process is increasingly less, and improvement on overall model training and model accuracy is not facilitated.

Based on the defects in the above implementation, model learning and the heterogeneous network are considered to be combined in the related art. In the heterogeneous network, a plurality of micro base stations are included in the coverage range of one macro base station, and the terminal is connected with the micro base stations for performing data and signaling interaction. The coverage range of the micro base stations is small, so when the terminal moves, switching is easily triggered. In the related art, a problem of terminal switching is not considered, so it cannot be determined whether the terminal, after being switched, continues to support training. In addition, during federated learning, as data type features of training data adopted by different nodes may be different, dimensions of training results of the different nodes may be different, and in the related art, a processing method for model learning based on the heterogeneous network is not considered.

Based on this, the disclosure provides a method for model learning. Model alignment processing is performed on model learning and a learning result of the heterogeneous network to determine a trained model needed by the OAM. Besides, a processing method after the terminal is switched is provided, and as for different model training task types, the terminal may continue to participate in a training task of a source micro base station (namely, the micro base station that accesses before terminal switching) or a training task that is added to a target micro base station (namely, a micro base station that accesses after terminal switching). The problem that the available training data is increasingly less in a terminal mobile scene is effectively solved. Besides, at different nodes, data used for model training is aligned and then trained, and it may be supported that the same model is trained by using different types of data.

Further, the macro base station and the micro base station involved in the disclosure belong to network devices, which may also be called wireless access network devices. The wireless access network device may be a base station, an evolved NodeB, a home NodeB, an access point (AP) in a wireless fidelity (WIFI) system, a wireless relay node, a wireless backhaul node, a transmission point (TP), a transmission and reception point (TRP), or the like, and may also be gNB in an NR system, or may also be a component or a part of devices constituting the base station, or the like. When it is a Vehicle-to-Everything (V2X) communication system, the network device may also be a vehicle-mounted device. It is to be understood that in the embodiment of the disclosure, a specific technology and a specific device form of the network device are not limited.

Further, the terminal involved in the disclosure may also be called a terminal device, user equipment (UE), a mobile station (MS), a mobile terminal (MT), or the like and is a device providing voice and/or data connectivity for a user, for example, the terminal may be a hand-held device, a vehicle-mounted device or the like with a wireless connection function. At present, examples of some terminals are: a mobile phone, a pocket personal computer (PPC), a palmtop computer, a personal digital assistant (PDA), a notebook computer, a tablet computer, a wearable device, a vehicle-mounted device or the like. Besides, when it is a Vehicle-to-Everything (V2X) communication system, the terminal device may also be a vehicle-mounted device. It is to be understood that in the embodiment of the disclosure, a specific technology and a specific device form of the terminal are not limited.

FIG. 1 is a schematic diagram of a scene architecture of a heterogeneous network of a method for model learning shown according to an example. As shown in FIG. 1, the system includes a macro base station, M micro base stations and N terminals. A terminal apparatus in the disclosure is mainly responsible for local data acquisition and local model training, a micro base station apparatus is mainly responsible for terminal scheduling and task assignment and coordinating the terminal apparatus to perform model training and terminal mobility management, a macro base station apparatus is mainly responsible for coordinating the micro base station apparatus to perform global model training so as to obtain a global model meeting the subscription demand of the OAM.

A coverage range of the micro base stations is within a coverage range of the macro base station. During signaling/data exchange between the macro base station and the micro base stations, it may be a wired connection, which, for example, is implemented through an optical fiber, a coaxial cable, a network cable and the like; and it may also be a wireless connection, which, for example, is implemented through a millimeter wave and the like. A connection between the macro base station and the micro base stations may be implemented through an X2 interface, or other interfaces such as an X3 interface, and the embodiments of the disclosure do not limit a specific implementation form of the connection.

A wireless connection may be established between the micro base stations and the terminal through a wireless radio. In different implementations, the wireless radio is a wireless radio based on a fourth generation mobile communication network technology (4G) standard; or the wireless radio is a wireless radio based on a fifth generation mobile communication network technology (5G) standard, for example, the wireless radio is a new radio; or the wireless radio may also be a wireless radio based on a next generation mobile communication network technology standard of 5G. The embodiments of the disclosure do not make a requirement for a specific implementation form of the connection between the terminals and the micro base stations within the range of the micro base stations. Based on the system, a method for model learning of the disclosure is provided.

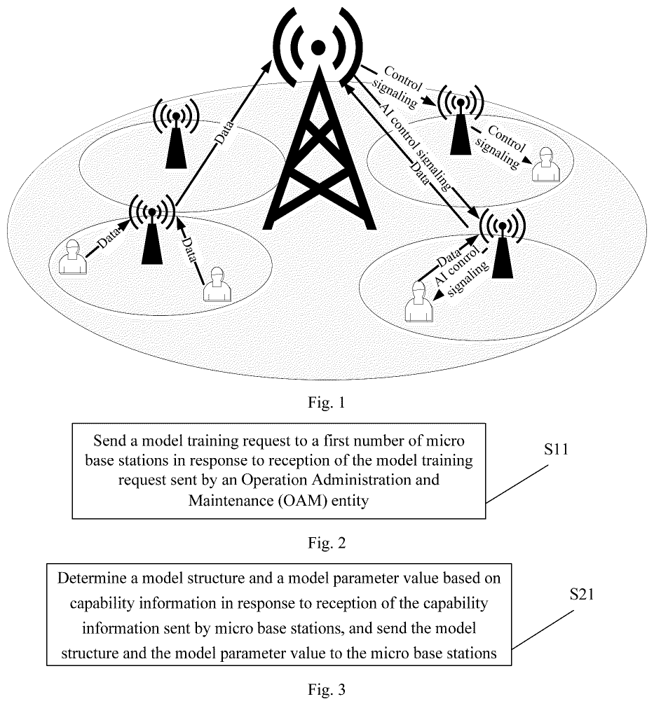

FIG. 2 is a flowchart of a method for model learning shown according to an example. As shown in FIG. 2, the method for model learning is performed by a macro base station and includes step S11.

In step S11, a model training request is sent to a first number of micro base stations in response to reception of the model training request sent by an operation administration and maintenance (OAM) entity.

In the embodiment of the disclosure, the OAM initiates the model training request to the macro base station, and the model training request includes a demand of the OAM for a training task type of a subscribed model, and model accuracy. The macro base station forwards, based on the received model training request, the model training request to the micro base stations through an X2 interface shown in FIG. 1. The number of forwarded model training requests is determined based on the number of micro base stations covered under the macro base station, and for convenient distinguishing, the disclosure calls the number of micro base stations covered under one macro base station a first number.

The model training request may at least include an analysis ID, a notification target address and analysis report information. The analysis ID is used for identifying an analysis type of the request; the notification target address is used for associating a notice received by a requested party with the subscription; and the analysis report information contains a preferred analysis accuracy level, an analysis time interval and other parameters. The model training request may further include analysis filter information, and the analysis filter information is used for indicating a condition that the analysis report information is to meet.

Through the method for model learning provided by the embodiment of the disclosure, the macro base station sends the received model training request to the micro base stations, so a data rate may be improved, and overall efficiency of a communication network is further improved.

In the embodiment of the disclosure, the macro base station sends the model training request to the micro base stations so as to cause the micro base stations to report capability information. The capability information reported by the micro base stations includes a communication condition and a local data type feature of a terminal that accesses the micro base stations, and a communication condition and a local data type feature of the micro base stations.

FIG. 3 is a flowchart of a method for model learning shown according to an example. As shown in FIG. 3, the method for model learning is performed by the macro base station and includes step S21.

In step S21, a model structure and a model parameter value are determined based on the capability information in response to reception of the capability information sent by the micro base stations, and the model structure and the model parameter value are sent to the micro base stations.

In the embodiment of the disclosure, the model structure is a model structure that the micro base stations are indicated to train based on the model training request, and the model parameter value is an initial parameter value of the model structure.

The macro base station performs model training task assignment based on the received capability information sent by the micro base stations, and determines a model structure and a model parameter value corresponding to each micro base station in the first number of micro base stations. The model training task assignment is to assign a specific task of federated learning of each micro base station. The corresponding model structure and model parameter value are sent to each micro base station.

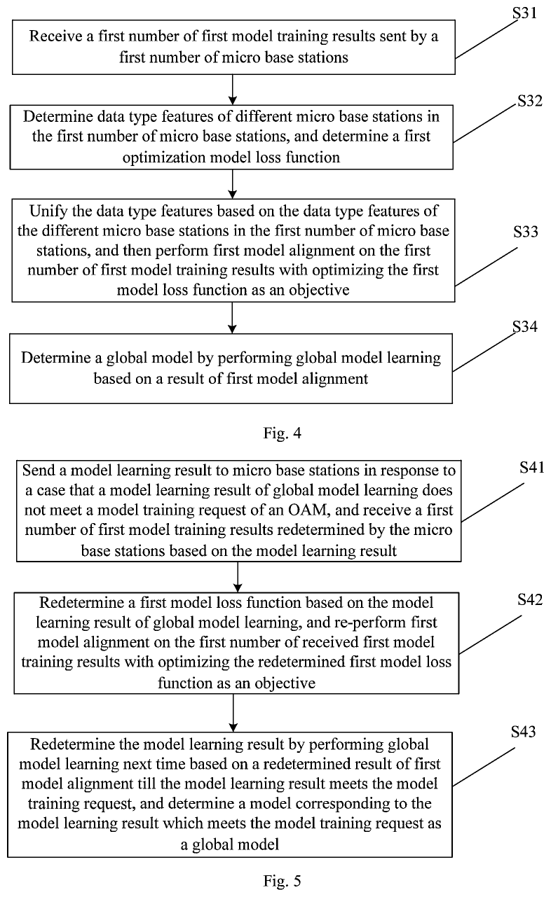

FIG. 4 is a flowchart of a method for model learning shown according to an example. As shown in FIG. 4, the method for model learning is performed by the macro base station and includes step S31-S34.

In step S31, a first number of first model training results sent by the first number of micro base stations are received.

In the embodiment of the disclosure, the macro base station receives a first model training result sent by each micro base station in the first number of micro base stations to obtain the first number of first model training results.

In step S32, data type features of different micro base stations in the first number of micro base stations are determined, and a first optimization model loss function is determined.

In the embodiment of the disclosure, the data type features of the different micro base stations are different, for example, a data type feature that one of the micro base stations has is image data, and a data type feature that another micro base station has is digital data. Certainly, this is merely an example and is not a specific limitation on the disclosure.

In step S33, the data type features are unified based on the data type features of the different micro base stations in the first number of micro base stations, and then first model alignment is performed on the first number of first model training results with optimizing the first model loss function as an objective.

In the embodiment of the disclosure, the macro base station performs dimension unifying on first data of first model training results obtained after federated learning of the micro base stations.

In some embodiments of the disclosure, the macro base station respectively performs one-dimensional convolution on the data type features obtained after federated learning of all (namely, the first number) the micro base stations under the coverage range of the macro base station, the data type features of all the micro base stations are mapped to the same dimension d′, and a specific formula is as follows:

$${\hat{X}}_{\{ {r}_{1} , {r}_{2} … {r}_{q} \}} = Conv 1 D ( {X}_{\{ {r}_{1} , {r}_{2} … {r}_{q} \}} , {k}_{\{ {r}_{1} , {r}_{2} … {r}_{q} \}} ) ∈ {R}^{{T}_{( {r}_{1} , {r}_{2} … {r}_{q} \}} \times {d}^{′}}$$

where r₁, r₂ . . . r_{q} represents q micro base stations connected under the macro base station, k_{{r}_{₁}_{,r}_{₂}_{. . . r}_{_{q}}_{}} is a size of a convolution kernel of the micro base stations {r₁, r₂ . . . r_{q}}, X_{{r}_{₁}_{,r}_{₂}_{. . . r}_{_{q}}_{}} represents the data type features obtained after federated learning of the micro base stations {r₁,r₂ . . . r_{q}}, d′ is a common dimension, and after one-dimensional convolution is performed, features of all the terminals are mapped to the same dimension d′, \hat{X}_{{r}_{₁}_{,r}_{₂}_{. . . r}_{_{q}}_{}} represents the data type features of the micro base stations {r₁, r₂ . . . r_{q}} are mapped to the common dimension, R^{T}{r₁,r₂ . . . r_{q}}^{×d}′ represents the data type feature matrix of the micro base stations {r₁,r₂ . . . r_{q}} are mapped to the common dimension.

Secondly, the macro base station, based on a dimension unifying result of all the micro base stations, performs first model alignment on the first number of first model training results with optimizing the first model loss function as an objective based on the data type features of the different micro base stations.

In step S34, a global model is determined by performing global model learning based on a result of first model alignment.

In the embodiment of the disclosure, the macro base station performs global model learning based on the result of first model alignment to obtain a model learning result. The model learning result is compared with the demand for the model training task type and the model accuracy included in the model training request, and then the global model requested by the OAM is determined.

FIG. 5 is a flowchart of a method for model learning shown according to an example. As shown in FIG. 5, the method for model learning is performed by the macro base station and includes steps S41-S43.

In step S41, a model learning result is sent to the micro base stations in response to a case that the model learning result of global model learning does not meet the model training request of the OAM, and the first number of first model training results redetermined by the micro base stations based on the model learning result are received.

In the embodiment of the disclosure, in response to a case that the macro base station determines that the model learning result of global model learning this time does not meet the model training request of the OAM, the model learning result of the global model learning this time is sent to the micro base stations for redetermining, by the micro base stations, a first model training result.

In step S42, a first model loss function is redetermined based on the model learning result of global model learning, and first model alignment is re-performed on the first number of received first model training results with optimizing the redetermined first model loss function as an objective.

In the embodiment of the disclosure, the first model loss function is redetermined based on the model learning result of global model learning this time that does not meet the model training request of the OAM, and first model alignment is re-performed on the first number of received first model training results with optimizing the redetermined first model loss function as an objective.

In step S43, a model learning result is redetermined by performing global model learning next time based on the redetermined result of first model alignment, till the model learning result meets the model training request, and a model corresponding to the model learning result which meets the model training request is determined as the global model.

In the embodiment of the disclosure, the macro base station performs global model learning again based on the redetermined result of first model alignment, namely, a result of re-optimizing the first model loss function so that the model learning result is obtained again. The model learning result obtained again is compared with the model training request to determine whether the demand of the model training request for a model is met. If the demand of the model training request for the model is not met, the first model loss function is redetermined till the model learning result of global model learning meets the model training request, and the model corresponding to the model learning result which meets the model training request is determined as the global model.

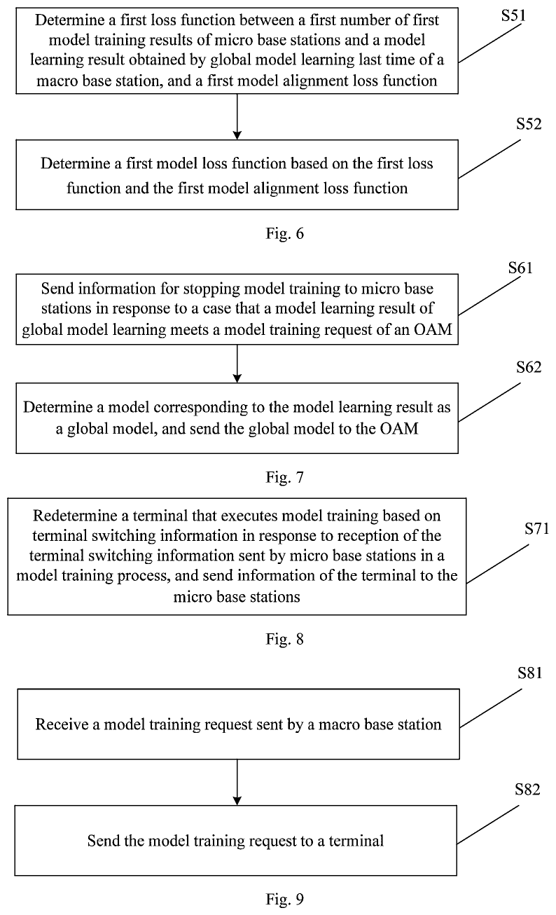

FIG. 6 is a flowchart of a method for model learning shown according to an example. As shown in FIG. 6, the method for model learning is performed by the macro base station and includes steps S51-S52.

In step S51, a first loss function between the first number of first model training results of the micro base stations and the model learning result obtained by global model learning last time of the macro base station, and a first model alignment loss function are determined.

In the embodiment of the disclosure, the first model loss function includes two parts, one part is the first loss function between the first number of first model training results of the micro base stations and the model learning result obtained by global model learning last time of the macro base station; and the other part is the first model alignment loss function. The macro base station performs first model alignment on the first number of first model training results with optimizing the first model loss function as an objective, in other words, the macro base station performs first model alignment on the first number of first model training results with optimizing an overall loss function of the first model alignment loss function and the first loss function as an objective.

In step S52, the first model loss function is determined based on the first loss function and the first model alignment loss function.

In the embodiment of the disclosure, the first loss function may be an absolute value error function and a squared error loss function for a regression problem and a cross entropy loss function for a classification problem and then the first model loss function is determined based on the first loss function and the first model alignment loss function.

In some embodiments of the disclosure, the first model loss function may refer to the following formula.

$$arg {min}_{Θ} {L}_{N} = {\sum }_{k = 1}^{q} l ( {r}_{t}^{k} , {a}_{t - 1} ) + η {l}_{M}$$

Where L_{N} represents the first model loss function, l(·, ·) represents the first loss function, namely, the absolute value error function and the squared error loss function for the regression problem, the cross entropy loss function for the classification problem and the like; l_{M} is the first model alignment loss function, η represents a weight factor; Θ represents all to-be-learned parameters, for example, a weight and a bias term; q represents the total number of micro base stations participating in federated learning; rₜ^{k} represents a first model training result of a federated aggregation parameter in a t^{th} time of federated learning process of the micro base stations k, and αₜ₋₁ represents a model learning result of global model learning in a (t-1)^{th} time of global learning process of the macro base station.

A functional expression of the first model alignment loss function l_{M} may be represented as:

$${l}_{M} = \frac{1}{4 {d}^{2}} {‖ {C}_{S} - {C}_{T} ‖}_{F}^{2}$$

∥·∥_{F}² represents a squared Hilbert-Schmidt matrix norm, and C_{S} and C_{T} represent a covariance matrix before model alignment and a covariance matrix after model alignment respectively, d is a common dimension.

FIG. 7 is a flowchart of a method for model learning shown according to an example. As shown in FIG. 7, the method for model learning is performed by the macro base station and includes S61-S62.

In step S61, information for stopping model training is sent to the micro base stations in response to a case that a model learning result of global model learning meets the model training request of the OAM.

In the embodiment of the disclosure, the information for stopping training indicates the micro base stations to stop a terminal from executing a model training task. The macro base station determines that a model learning result of current global model learning meets the model training request of the OAM. In other words, the subscription demand in the model training request sent by the OAM contains a specific requirement proposed for model accuracy needed by a subscribed service, when the model learning result of global model learning meets the subscription demand of the OAM, it means that the current global learning model has reached the sufficient accuracy, ending the training task is determined, and the available global model is obtained. The information for stopping model training is sent to the micro base stations. The information for stopping training indicates the micro base stations to stop the terminal from executing the model training task.

In step S62, the model corresponding to the model learning result is determined as the global model, and the global model is sent to the OAM.

In the embodiment of the disclosure, taking the current time being the t^{th} time of global model learning as an example, the model learning result of t^{th} time of global model learning is represented by at, and then at is sent to the OAM.

FIG. 8 is a flowchart of a method for model learning shown according to an example. As shown in FIG. 8, the method for model learning is performed by the macro base station and includes steps S71.

In step S71, a terminal that executes model training is redetermined based on terminal switching information in response to reception of the terminal switching information sent by the micro base stations in a model training process, and information of the terminal is sent to the micro base stations.

In the embodiment of the disclosure, in response to reception, by the macro base station, of the terminal switching information sent by the micro base stations, it is determined that the terminal that executes the model training task exits or a terminal that newly accesses the micro base stations exists. The macro base station redetermines, based on the received terminal switching information, a terminal that executes the model training task and sends terminal information of the redetermined terminal that executes the model training task to the micro base stations. The terminal switching information includes information of a terminal that exits model training and a target micro base station that the terminal re-accesses. The terminal switching information is used for redetermining, by the macro base station, the terminal that executes the model training task. The macro base station judges whether to exit the connection or whether the newly-added terminal participates in executing the model training task according to a switching situation of the terminal. The macro base station judges whether to exit the connection or whether the newly-added terminal continues participating in the training task of a source micro base station according to a training task type in the subscribed demand of the OAM.

In some embodiments of the disclosure, the training task type may be divided into a task related to an upper-layer application and a task related to a bottom-layer network channel. If the task is related to the upper-layer application, the terminal may continue participating in a federated learning task of the source micro base station; if the task is related to the bottom-layer network channel, a trained model is merely applicable to the source micro base station (namely, the micro base station that accesses before terminal switching), and the terminal cannot continue participating in the federated learning task of the source micro base station. The macro base station may determine whether the terminal continues participating in training of the source micro base station according to the training task type in the subscribed demand of the OAM and specific switching information.

In an embodiment, the macro base station determines that the terminal continues participating in the model training task of the source micro base station, so a target micro base station (namely, a micro base station that accesses after terminal switching) is responsible for forwarding the first model training result between the terminal and the source micro base station, and the source micro base station continues preserving the terminal in a training task list and reassigns a model training task to the terminal. The target micro base station sends a task arrangement result of the terminal to the terminal, and the terminal preserves training information in the source micro base station and continues participating in federated learning of the source micro base station.

In an embodiment, the macro base station determines that the terminal continues participating in training of the source micro base station, so the target micro base station is responsible for forwarding the first model training result between the terminal and the source micro base station. When the terminal completes one round of local model training, the terminal sends a local training result to the target micro base station, and the target micro base station forwards the result to the source micro base station; and when the macro base station completes one round of global model learning, the source micro base station sends a global learning result and signaling of whether the terminal continues training to the target micro base station, and the target micro base station forwards the data and the signaling to the terminal.

Based on the same/similar concept, an embodiment of the disclosure further provides a method for model learning.

FIG. 9 is a flowchart of a method for model learning shown according to an example. As shown in FIG. 9, the method for model learning is performed by micro base stations and includes steps S81-82.

In step S81, a model training request sent by a macro base station is received.

In step S82, the model training request is sent to a terminal.

In the embodiment of the disclosure, the number of micro base stations receiving the model training request is a first number; and a communication coverage range of the first number of micro base stations is within a communication coverage range of the macro base station. The micro base stations forward, after receiving the model training request sent by the macro base station, the model training request to the terminal.

In the embodiment of the disclosure, the micro base stations send the model training request to the terminal, and the model training request may be used for triggering the terminal to send a communication condition and a data type feature of the terminal.

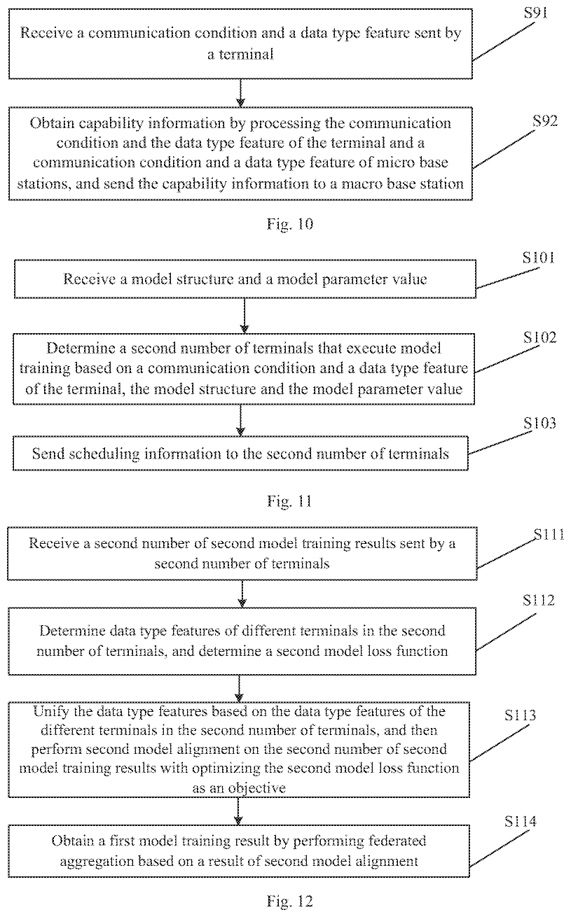

FIG. 10 is a flowchart of a method for model learning shown according to an example. As shown in FIG. 10, the method for model learning is performed by micro base stations and includes steps S91-S92.

In step S91, a communication condition and a data type feature sent by a terminal are received.

In step S92, capability information is obtained by processing the communication condition and the data type feature of the terminal and a communication condition and a data type feature of the micro base stations, and the capability information is sent to the macro base station.

In the embodiment of the disclosure, the terminal receives a model training request sent by the micro base stations and determines and reports its own communication condition and data type feature. Data and signaling interaction is performed between the micro base stations and the terminal through a wireless channel. In an implementation, the communication condition reported by the terminal refers to communication capability or a communication channel condition of the terminal. In an implementation, the communication condition reported by the terminal to the micro base stations may contain channel quality indication (CQI) information obtained by terminal detection. The local data feature reported by the terminal may contain a category and the like of collected data. The micro base stations send the communication condition and the data type feature reported by the terminal and the communication condition and the data type feature of the micro base stations to the macro base station through an X2 interface. For convenient description, the disclosure calls the communication condition and the data type feature of the terminal and the communication condition and the data type feature of the micro base stations the capability information. The capability information is used for determining, by the macro base station, a model structure and a model parameter value.

FIG. 11 is a flowchart of a method for model learning shown according to an example. As shown in FIG. 11, the method for model learning is performed by the micro base stations and includes steps S101-S103.

In step S101, the model structure and the model parameter value are received.

In the embodiment of the disclosure, the model structure is a model structure that the micro base stations are indicated to train based on the model training request, and the model parameter value is an initial parameter value of the model structure.

In step S102, a second number of terminals that execute model training is determined based on the communication condition and the data type feature of the terminal, the model structure and the model parameter value.

In the embodiment of the disclosure, the micro base stations determine the second number of terminals that execute a model training task based on the received model structure and model parameter value as well as the communication condition and the data type feature of the accessing terminal.

In step S103, scheduling information is sent to the second number of terminals.

In the embodiment of the disclosure, the micro base stations, after determining the second number of terminals, send the scheduling information to the second number of terminals. The scheduling information includes the model structure, the model parameter value as well as indication information for indicating the terminals to perform model training.

In a mode, the micro base stations determine that the terminals that execute the model training task include one terminal (namely, the second number is one), so the micro base stations determine that a learning mode of the terminal is a single-terminal training mode. The micro base stations directly forward a training task assigned by the macro base station to the terminal, and the terminal may perform local model training according to the assigned task.

In another mode, the micro base stations determine that the terminals that execute the model training task include a plurality of terminals (namely, the second number is multiple), so the micro base stations determine that a learning mode of the terminal is a multi-terminal collaborative training mode. The micro base stations assign training tasks assigned by the macro base station according to communication conditions and local data features of different terminals for assisting the plurality of terminals in collaboratively completing model training, and each terminal may perform local model training according to the model training task assigned by the micro base stations after receiving the task assigned by the micro base stations.

In some embodiments of the disclosure, the terminal performs initialization on a local model parameter after receiving the scheduling information sent by the micro base stations, then performs local model training according to a demand of the model training task assigned by the micro base stations and transmits a training result to the micro base stations through a wireless channel.

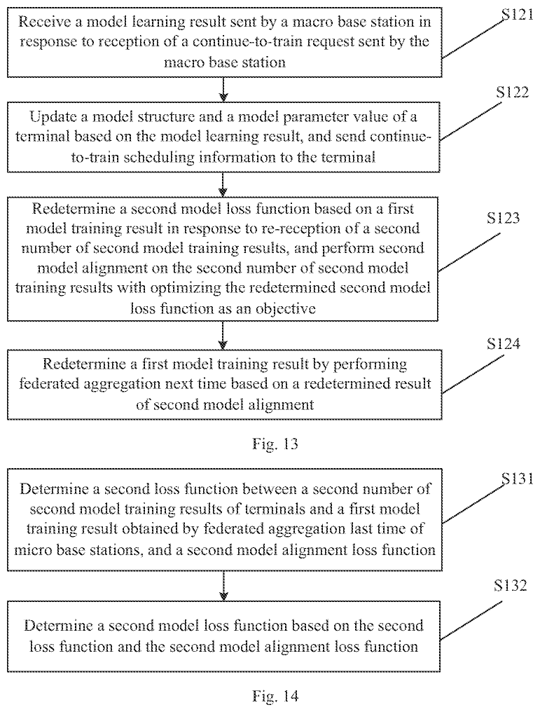

FIG. 12 is a flowchart of a method for model learning shown according to an example. As shown in FIG. 12, the method for model learning is performed by the micro base station and includes steps S111-S114.

In step S111, a second number of second model training results sent by the second number of terminals are received.

In the embodiment of the disclosure, the micro base stations receive the second number of second model training results sent by the second number of terminals. The terminal m in the second number of terminals is taken as an example. The terminal m randomly initializes a group of model parameters as initialized parameters of a local learning model, and a result of the initialized local learning model is recorded as w₀^{m}. The terminal m generates a local data set Dₘ by sensing and collecting data, randomly extracts a data set of a data volume N from the local data set, and generates a local training set Tₘ, after the local model parameter is initialized, the terminals perform local model training by using the local training set, training results of the terminals (namely, the second model training results) are transmitted to the micro base stations through a wireless channel, and taking the t^{th} time of federated learning process as an example, a local learning model training updating result transmitted by the terminal m may be represented as wₜ^{m}.

In step S112, data type features that different terminals in the second number of terminals have are determined, and a second model loss function is determined.

In the embodiment of the disclosure, the data type feature that each terminal in the second number of terminals has is determined. The different data type features include image data, digital data and the like.

In step S113, the data type features are unified based on the data type features that the different terminals in the second number of terminals have, and then second model alignment is performed on the second number of second model training results with optimizing the second model loss function as an objective.

In the embodiment of the disclosure, as the data type features of the local data set of the terminals may be different, dimensions of local model features obtained by training may also be different, and thus different terminal feature dimensions are unified so as to facilitate model alignment and federated aggregation. One-dimensional convolution is respectively performed on features of all the terminals after training is completed under the micro base station i, the features of all the terminals are mapped to the same dimension d, and a specific formula is as follows:

$${\hat{X}}_{\{ {m}_{1} , {m}_{2} … {m}_{n} \}} = Conv 1 D ( {X}_{\{ {m}_{1} , {m}_{2} … {m}_{n} \}} , {k}_{\{ {m}_{1} , {m}_{2} … {m}_{n} \}} ) ∈ {R}^{{T}_{( {m}_{1} , {m}_{2} … {m}_{n} \}} \times d}$$

where m₁, m₂ . . . mₙ represent n terminals connected under the micro base station i, k{m₁,m₂ . . . mₙ} is a size of a convolution kernel of the terminals {m₁, m₂ . . . mₙ}, X_{{m}_{₁}_{,m}_{₂}_{. . . m}_{ₙ}_{}} represents the data type features obtained after training of the terminals {m₁, m₂ . . . mₙ}, d is a common dimension, and after one-dimensional convolution is performed, the features of all the terminals are mapped to the same dimension d. The micro base stations, based on a dimension unifying result of all the terminals, perform second model alignment on the second number of second model training results with optimizing the first model loss function as an objective based on the data type features of the different terminals, \hat{X}_{{m}_{₁}_{,m}_{₂}_{. . . m}_{ₙ}_{}} represents the data type features of the terminals {m₁, m₂ . . . mₙ} are mapped to the common dimension, R^{T}{m₁,m₂ . . . mₙ}^{×d} represents the data type feature matrix of the terminals {m₁, m₂ . . . mₙ} are mapped to the common dimension.

In step S114, a first model training result is obtained by performing federated aggregation based on a result of second model alignment.

In the embodiment of the disclosure, the micro base stations perform federated learning based on the result of second model alignment to obtain the first model training result. Afterwards, the first model training result is sent to the macro base station.

FIG. 13 is a flowchart of a method for model learning shown according to an example. As shown in FIG. 13, the method for model learning is performed by the micro base stations and includes steps S121-S124.

In step S121, a model learning result sent by the macro base station is received in response to reception of a continue-to-train request sent by the macro base station.

In the embodiment of the disclosure, if the continue-to-train request sent by the macro base station is received, the model learning result sent by the macro base station is further received.

In step S122, the model structure and the model parameter value of the terminal are updated based on the model learning result, and continue-to-train scheduling information is sent to the terminal.

In the embodiment of the disclosure, the micro base stations send the model learning result sent by the macro base station to the terminal, and the terminal updates the model structure and the model parameter value based on the model learning result. The micro base stations send the continue-to-train scheduling information to the terminal so that the terminal is indicated to continue executing the model training task based on the updated model structure and model parameter value, and a second model training result obtained again is sent to the micro base stations again.

In step S123, the second model loss function is redetermined based on the first model training result in response to re-reception of a second number of second model training results, and second model alignment is performed on the second number of second model training results with optimizing the redetermined second model loss function as an objective.

In the embodiment of the disclosure, the micro base stations, after re-receiving the second number of second model training results sent by the terminal, redetermine a second loss function based on the received first model training result sent by the macro base station, and re-perform second model alignment on the second number of second model training results with optimizing the second loss function as an objective.

In step S124, a first model training result is redetermined by performing federated aggregation next time based on a redetermined result of second model alignment.

In the embodiment of the disclosure, based on the redetermined result of second model alignment, taking the micro base station i as an example, the micro base station i performs federated aggregation based on model alignment. After federated aggregation is completed, the micro base station reports a federated aggregation result to the macro base station through an X2 interface, and taking the t^{th} time of federated learning process as an example, the federated aggregation result transmitted by the micro base station i may be represented as rₜⁱ. The first model training result is redetermined by performing federated aggregation. Federated learning cyclic interaction among the macro base station, the micro base station and the terminal is formed till the macro base station finally determines a global model that meets a demand of the OAM.

FIG. 14 is a flowchart of a method for model learning shown according to an example. As shown in FIG. 14, the method for model learning is performed by the micro base stations and includes steps S131-S132.

In step S131, a second loss function between the second number of second model training results of the terminals and the first model training result of the micro base stations obtained by federated aggregation last time, and a second model alignment loss function are determined.

In step S132, the second model loss function is determined based on the second loss function and the second model alignment loss function.

In the embodiment of the disclosure, feature dimensions of all the terminals are unified, then model alignment is performed based on feature alignment results of the different terminals, in a model alignment process, with optimizing the second model loss function as an objective, the second model loss function may be determined by two parts, the first part is obtained by calculating a loss function by model training results of a t^{th} time of federated learning of all the terminals and an updating result of a (t-1)^{th} time of federated learning of the micro base stations; and the second part is obtained by calculating a loss function after and before model alignment. Optimizing an overall loss function of the two parts is used as an objective of model alignment.

The second loss function may be an absolute value error function and a squared error loss function for a regression problem and a cross entropy loss function for a classification problem, and then the second model loss function is determined based on the second loss function and the second model alignment loss function.

In some embodiments of the disclosure, the second model loss function may refer to the following formula.

A second loss function of the micro base station i in the t^{th} time of federated training process may be represented as:

$$arg {min}_{Θ} {L}_{N} = {\sum }_{k = 1}^{q} l ( {r}_{t}^{k} , {a}_{t - 1} ) + η {l}_{M}$$

where L_{M} represents the second model loss function, l(·, ·) represents the second loss function, namely, the absolute value error function and the squared error loss function for the regression problem, the cross entropy loss function for the classification problem and the like; l_{M} is the model alignment loss function, and η represents a weight factor; Θ represents all to-be-learned parameters, for example, a weight and a bias term; n represents the total number of terminals participating in federated learning under the micro base station i; wₜ^{k} represents a local learning model training updating result in a t^{th} time of federated learning process of the terminal k; and rₜ₋₁ⁱ represents a training updating result of a federated aggregation parameter in a (t-1)^{th} time of federated learning process of the micro base station i.

The model alignment loss function may be represented as:

$${l}_{M} = \frac{1}{4 {d}^{2}} {‖ {C}_{S} - {C}_{T} ‖}_{F}^{2}$$

where ∥·∥_{F}² represents a squared Hilbert-Schmidt matrix norm, and C_{S} and C_{T} represent a covariance matrix before model alignment and a covariance matrix after model alignment respectively, d is a common dimension.

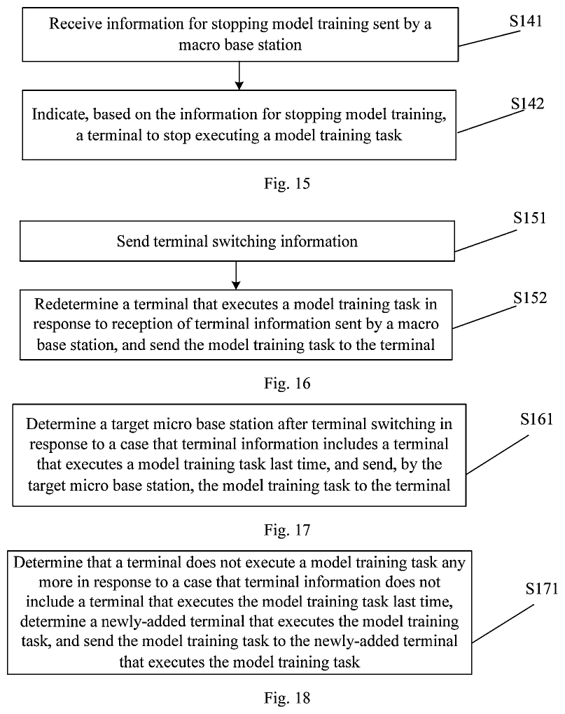

FIG. 15 is a flowchart of a method for model learning shown according to an example. As shown in FIG. 15, the method for model learning is performed by the micro base stations and includes steps S141-S142.

In step S141, information for stopping model training sent by the macro base station is received.

In the embodiment of the disclosure, the information for stopping training is used for indicating the micro base stations to stop the terminal from executing the model training task.

In step S142, the terminal is indicated to stop executing the model training task based on the information for stopping model training.

In the embodiment of the disclosure, if the micro base stations receive the information for stopping model training, it is determined that a model is not trained any more. The information for stopping model training is sent to the terminal so as to indicate the terminal to stop executing the model training task.

FIG. 16 is a flowchart of a method for model learning shown according to an example. As shown in FIG. 16, the method for model learning is performed by the micro base stations and includes steps S151-S152.

In step S151, terminal switching information is sent.

In the embodiment of the disclosure, the terminal switching information includes information of a terminal that exits model training and a target micro base station that the terminal re-accesses. The terminal switching information is used for redetermining, by the macro base station, the terminal that executes the model training task.

In some embodiments of the disclosure, the source micro base station represents a micro base station that the terminal accesses before terminal switching, and the target micro base station represents a micro base station that the terminal accesses after terminal switching. The source micro base station sends a measurement control signal to the terminal regularly, the terminal measures reference signal receiving power, reference signal receiving quality and the like according to the measurement control signal, and reports a measurement report to the source micro base station. When the source micro base station detects that other base stations may provide higher service quality for the terminal, the source micro base station makes a terminal switching decision, notifies the terminal to prepare for executing switching and initiates a switching request to the target micro base station, and meanwhile, reports information of the switched terminal and the target micro base station to the connected macro base station. The source micro base station sends a reconfiguration RRC connection request message to the terminal, and meanwhile, sends terminal status information to the target micro base station, the terminal and the target micro base station perform a series of parameter configurations, the terminal successfully accesses the target micro base station, and the target micro base station sends a successful switching message to the source micro base station.

In step S152, the terminal that executes the model training task is redetermined in response to reception of terminal information sent by the macro base station, and the model training task is sent to the terminal.

In the embodiment of the disclosure, the micro base station, after receiving the terminal information sent by the macro base station, reassigns a model training task of each terminal based on the redetermined terminal that executes the model training task and sends the corresponding model training task to the terminal.

FIG. 17 is a flowchart of a method for model learning shown according to an example. As shown in FIG. 17, the method for model learning is performed by the micro base station and includes step S161.

In step S161, the target micro base station after terminal switching is determined in response to a case that the terminal information includes the terminal that executes the model training task last time, and the target micro base station sends the model training task to the terminal.

In the embodiment of the disclosure, the micro base station that the terminal is switched to access redetermines the terminal that executes the model training task based on the terminal information sent by the macro base station. If the terminal information includes the terminal that executes the model training task last time and the terminal has been switched to another micro base station, the target micro base station (namely, the micro base station that the terminal accesses after terminal switching) is responsible for forwarding the second model training result between the terminal and the source micro base station (namely, the micro base station that the terminal accesses before terminal switching), and the source micro base station continues preserving the terminal in a training task list and reassigns a training task to the terminal. The target micro base station sends the model training task of the terminal to the terminal, and the terminal preserves training information in the source micro base station and continues participating in federated learning of the source micro base station.

FIG. 18 is a flowchart of a method for model learning shown according to an example. As shown in FIG. 18, the method for model learning is performed by the micro base station and includes step S171.

In step S171, it is determined that the terminal does not execute the model training task any more in response to a case that the terminal information does not include the terminal that executes the model training task last time, a newly-added terminal that executes the model training task is determined, and the model training task is sent to the newly-added terminal that executes the model training task.

In the embodiment of the disclosure, a training task type of the source micro base station does not support the terminal continuing participating in training, then the source micro base station completely removes the terminal out of training, the new terminal reports a communication condition and a local data feature to the target micro base station, and the target micro base station determines whether the new terminal participates in training of the target micro base station according to the training task type and information reported by the new terminal. The target micro base station sends a task arrangement result of the terminal to the terminal.

Further, the micro base station that the terminal is switched to access redetermines the terminal that executes the model training task based on the terminal information sent by the macro base station. If the terminal information does not include the terminal that executes the model training task last time and the terminal has been switched to another micro base station, the target micro base station is responsible for forwarding the second model training result between the terminal and the source micro base station. When the terminal completes one round of local model training, the terminal sends a local training result to the target micro base station, and the target micro base station forwards the result to the source micro base station When the macro base station completes one round of global model learning, the source micro base station sends a model learning result and signaling of whether the terminal continues training to the target micro base station, and the target micro base station forwards the data and the signaling to the terminal. The micro base station removes the terminal that does not execute the model training task any more out of the training task list. The newly-added terminal that participates in executing the model training task is determined, and the newly-added terminal reports the communication condition and the local data feature to the target micro base station through a wireless channel. The target micro base station determines whether the newly-added terminal participates in executing the model training task according to a type of the model training task and the information reported by the newly-added terminal. Whether the terminal participates in training of the source micro base station, the target micro base station sends the task arrangement result of the terminal to the terminal through the wireless channel.

In some embodiments of the disclosure, an interaction process among the macro base station, the micro base station and the terminal is described.

The OAM initiates the model training request to the macro base station, the macro base station forwards, after receiving the request, the model training request to the micro base stations, the micro base stations forward the request to the terminal, the terminal reports the communication condition and the local data feature to the micro base stations, and the micro base stations report the terminal information to the macro base station. The macro base station performs task assignment on the micro base station according to the terminal information reported by the micro base station and issues a model structure and hyper-parameter information (namely, the model parameter value involved in the embodiment of the disclosure) to the micro base station. The micro base station selects, after receiving the information issued by the macro base station, the terminal that participates in training and a learning mode of the terminal, and performs task assignment on the terminal that participates in the model training task. The terminal, the micro base station and the macro base station are in continuous iteration for performing federated learning till a model meets a subscription demand (for example, a model accuracy demand) of the OAM, and the macro base station reports the model training result (namely, the model learning result of global model learning) to the OAM.

The subscription demand of the OAM includes an analysis ID which is used for identifying an analysis type of the request; a notification target address which is used for associating a notice received by a requested party with the subscription; analysis report information containing a preferred analysis accuracy level, an analysis time interval and other parameters; and analysis filter information (optional) which indicates a condition that analysis report information is to meet.

In some embodiments, a specific method for federated learning by iteration of the terminal, the micro base station and the macro base station includes:

in a federated learning process, the terminal performs initialization on a local model parameter firstly, then performs local model training according to a demand of the task assigned by the micro base station and transmits a training result (namely, the second model training result) to the micro base station through a wireless channel. The micro base station, after gathering local training results of all the terminals that participate in training, performs model alignment, then performs federated aggregation, and reports a federated aggregation result (namely, the first model training result) to the macro base station through the X2 interface. The macro base station, after gathering federated aggregation results of all the micro base stations that participate in training, performs model alignment, then performs global model learning and sends the global learning result to the micro base station through the X2 interface. The micro base station forwards the global model training result to the terminal through the wireless channel, and the terminal updates a local learning model according to the global model training result. The macro base station judges whether a global training model meets the requirement according to the subscription demand of the OAM.

In some embodiments, if performance of the global model meets the subscription demand of the OAM, the macro base station reports the model training result to the OAM and notifies the micro base station to stop training.

In some embodiments, if the performance of the global model does not meet the subscription demand of the OAM, the macro base station needs to arrange the training task of the terminal according to the terminal switching information, the micro base station re-performs task assignment according to a terminal switching situation, the terminal re-performs local model learning and reports a result to the micro base station, and iteration is repeated like this till the model performance meets the subscription demand of the OAM.

In some embodiments, in a terminal switching process, the source micro base station represents the micro base station that the terminal accesses before terminal switching, and the target micro base station represents the micro base station that the terminal accesses after terminal switching. Arranging, by the macro base station, the terminal to execute the model training task according to the terminal switching information includes:

when the source micro base station makes a terminal switching decision in a certain cycle of federated learning, the source micro base station notifies the terminal to prepare for executing switching, and reports information of the terminal that exists the connection and the target micro base station to the macro base station. The terminal executes, after receiving a command from the source micro base station, switching and completes connection to the target micro base station. The macro base station determines whether the terminal continues participating in training of the source micro base station according to a training task type of the source micro base station and the terminal switching information.

In some embodiments, the training task type of the source micro base station supports the terminal continuing participating in training, then the target micro base station is responsible for forwarding training data between the terminal and the source micro base station, the terminal continues participating in the training task of the source micro base station, and the target micro base station sends the task arrangement result of the terminal to the terminal.

In some embodiments, the training task type of the source micro base station does not support the terminal continuing participating in training, then the source micro base station completely removes the terminal out of training, the new terminal reports the communication condition and the local data feature to the target micro base station, and the target micro base station determines whether the new terminal participates in training of the target micro base station according to the training task type and information reported by the new terminal. Then the target micro base station sends the task arrangement result of the terminal to the terminal.

In some embodiments, the macro base station, the micro base stations and the terminal complete the model training task of the OAM, and after the global model is sent to the OAM, inference may further be performed on the model obtained by training. The OAM determines a task cell for performing model inference, and an implementation for performing task inference by the task cell includes:

when task inference is to be performed, the task cell initiates an inference request to the OAM through the macro base station where the task cell is located and reports an inference task type and a specific demand, and the OAM finds one or more appropriate models according to the inference task type and the specific demand. When the appropriate model is found, the OAM issues a model selection result to the macro base station, and the selected macro base station reports specific model parameter information. The OAM forwards the model parameter information reported by the selected macro base station to the macro base station where the task cell is located, and the macro base station where the task cell is located performs inference on a task according to the model parameter information.

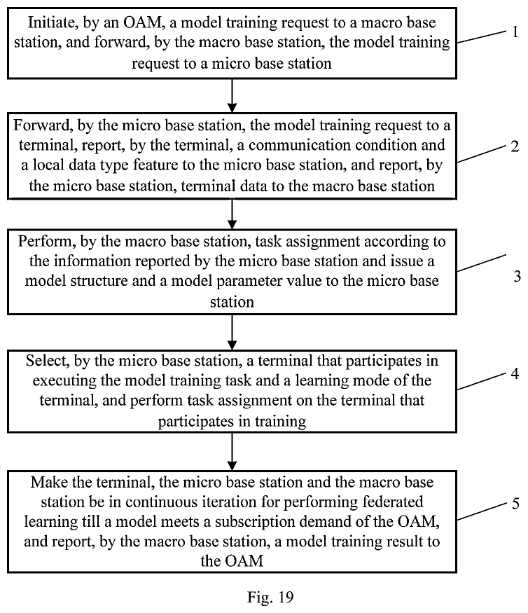

The following embodiment will describe the interaction process among the macro base station, the micro base stations and the terminal with reference to the accompanying drawings. FIG. 19 is a main flowchart of a model inference method shown according to an example. As shown in FIG. 19, the model may include the following steps:

step 1, an OAM initiates a model training request to a macro base station, and the macro base station forwards the model training request to a micro base station;

step 2, the micro base station forwards the model training request to a terminal, the terminal reports a communication condition and a local data type feature to the micro base station, and the micro base station reports the terminal data to the macro base station;

step 3, the macro base station performs task assignment according to the information reported by the micro base station and issues a model structure and a model parameter value to the micro base station;

step 4, the micro base station selects a terminal that participates in executing the model training task and a learning mode of the terminal, and performs task assignment on the terminal that participates in training; and

step 5, the terminal, the micro base station and the macro base station are in continuous iteration for performing federated learning till a model meets a subscription demand of the OAM, and the macro base station reports a model training result to the OAM.

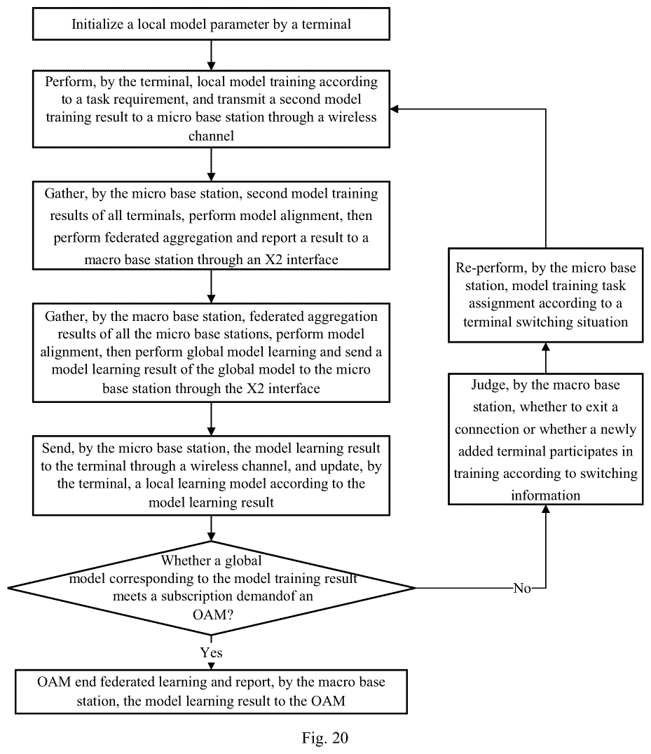

FIG. 20 is a flowchart of federated learning of a model inference method shown according to an example. As shown in FIG. 20, the model includes: the terminal performs initialization on a local model parameter; the terminal performs local model training according to a task requirement and transmits a second model training result to the micro base station through a wireless channel; the micro base station gathers second model training results of all terminals, performs model alignment, then performs federated aggregation, and reports a result to the macro base station through an X2 interface; the macro base station gathers federated aggregation results of all the micro base stations, performs model alignment, then performs global model learning, and sends a model learning result of a global model to the micro base station through the X2 interface; the micro base station sends the model learning result to the terminal through the wireless channel, and the terminal updates a local learning model according to the model learning result; the macro base station determines whether the global model corresponding to the model training result meets the subscription demand of the OAM; and if the subscription demand of the OAM is met, federated learning ends, and the macro base station reports the model learning result to the OAM. If the subscription demand of the OAM is not met, the macro base station judges whether to exit a connection or whether the new connected terminal participates in training according to switching information, and the micro base station re-performs model training task assignment according to a terminal switching situation.

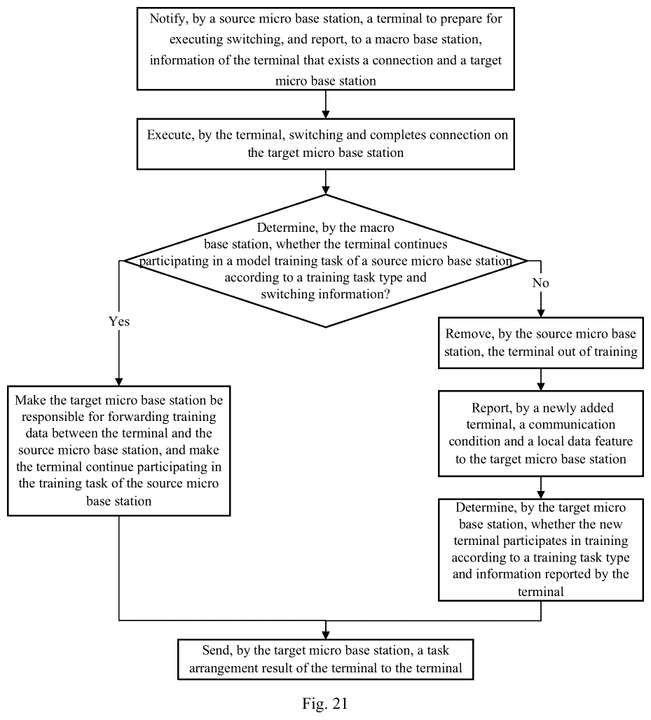

FIG. 21 is a flowchart of terminal switching processing in a method for model learningshown according to an example. As shown in FIG. 21, the model includes: a source micro base station notifies the terminal to prepare for executing switching, and reports information of the terminal that exists the connection and a target micro base station to the macro base station; the terminal executes switching and completes connection to the target micro base station; the macro base station determines whether the terminal continues participating in a model training task of the source micro base station according to a training task type and the switching information; if the terminal continues participating in executing the model training task of the source micro base station, the target micro base station is responsible for forwarding training data between the terminal and the source micro base station, and the terminal continues participating in the training task of the source micro base station; and the target micro base station sends a task arrangement result of the terminal to the terminal. If the terminal does not continue participating in executing the model training task of the source micro base station, the source micro base station removes the terminal out of training; the newly-added terminal reports a communication condition and a local data feature to the target micro base station; the target micro base station determines whether the new terminal participates in training according to the training task type and the information reported by the new terminal; and the target micro base station sends the task arrangement result of the terminal to the terminal.

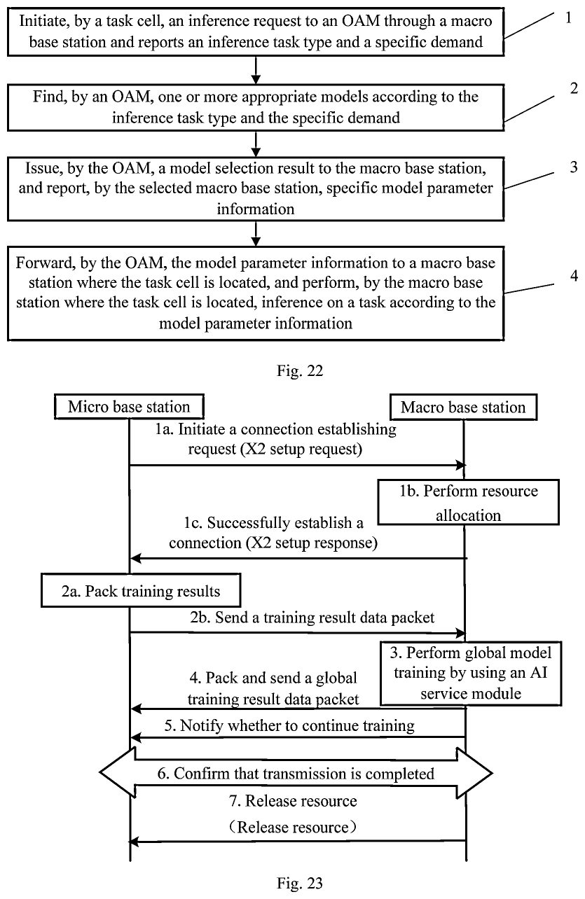

In some embodiments of the disclosure, after the global model is determined, further includes: inferring the global model. FIG. 22 is a flowchart of model inference of a method for model learning shown according to an example. As shown in FIG. 22, the model includes the following steps:

step 1, a task cell initiates an inference request to an OAM through a macro base station and reports an inference task type and a specific demand; and

step 2, the OAM finds one or more appropriate models according to the inference task type and the specific demand.

In an embodiment, the inference task type may be divided into a type related to an upper-layer application and a type related to a bottom-layer network channel. During model selection, a macro base station model of which the training task type and the inference task type are close is selected preferentially.

In an embodiment, a plurality of well-trained models may be selected, are fused and then subjected to inference.

Step 3, the OAM issues a model selection result to the macro base station, and the selected macro base station reports specific model parameter information.

Step 4, the OAM forwards the model parameter information to the macro base station where the task cell is located, and the macro base station where the task cell is located performs inference on a task according to the model parameter information.

In an embodiment, the OAM selects the plurality of well-trained macro base station models, and then the macro base station where the task cell is located performs model fusion on the plurality of models and then performs inference on the task.

FIG. 23 is a principle diagram of a protocol and an interface for signaling and data transmission performed between a micro base station and a macro base station in a method for model learning shown according to an example. As shown in FIG. 23, interaction between the micro base station and the macro base station is mainly involved and is specifically as follows:

1a. the micro base station sends, to the macro base station, signaling of sending a connection establishing request (X2 setup request), a signaling indication content being request for establishing a connection to a target base station; 1b. the macro base station performs resource allocation according to the connection establishing request signaling sent by the micro base station; 1c. the macro base station sends, to the micro base station, signaling of successfully establishing a connection (X2 setup response), a signaling indication content being notifying a counterpart that the connection has been successfully established; 2a. the micro base station packs the first model training results; 2b. the micro base station sends, to the macro base station, signaling of sending a training result data packet, a signaling indication content being sending the training data packet to a receiver; 3. The macro base station performs global model training by using an AI service module; 4. the macro base station sends, to the micro base station, signaling of packing and sending a global model training result data packet, a signaling indication content being packing global model training results and sending a data packet to a receiver; 5. the macro base station sends, to the micro base station, signaling of notifying whether to continue training, a signaling indication content being notifying a counterpart of whether to continue training; 6. the macro base station and the micro base station determine that transmitting is completed; and 7. the macro base station sends resource releasing signaling (release resource) to the micro base station, a signaling indication content being to perform resource releasing;

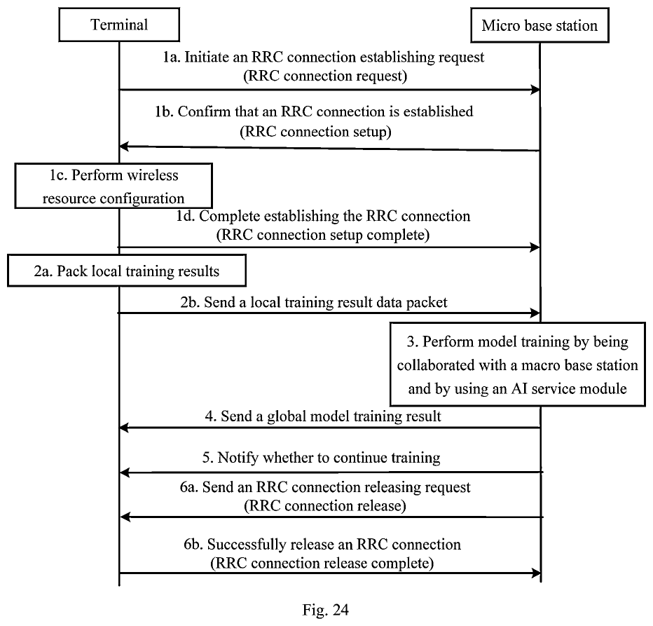

FIG. 24 is a principle diagram of a protocol and an interface for signaling and data transmission performed between a micro base station and a terminal in a method for model learning shown according to an example. As shown in FIG. 24, interaction between the micro base station and the terminal is mainly involved and is specifically as follows:

1a. the terminal sends, to the micro base station, signaling of sending an RRC connection establishing request (RRC connection request), a signaling indication content being request for establishing an RRC connection to a target base station; 1b. the micro base station sends signaling of confirming to establish the RRC connection (RRC connection setup) to the terminal, a signaling indication content being notifying the receiver that establishing the RRC connection is confirmed; 1c. the terminal performs wireless resource configuration according to the signaling sent by the micro base station; 1d. the terminal sends, to the micro base station, signaling of completing establishing the RRC connection (RRC connection setup complete), a signaling indication content being notifying the receiver that establishing the RRC connection is completed; 2a. the terminal packs local training results (namely, the second model training results); 2b. the terminal sends, to the micro base station, signaling of sending a local training result data packet, a signaling indication content being sending the local training result data packet to the receiver; 3. the micro base station and the macro base station collaboratively use the AI service module to perform model training; 4. the micro base station sends, to the terminal, signaling of sending global model training result, a signaling indication content being sending global model training results to the receiver; 5. the micro base station sends, to the terminal, signaling of notifying whether to continue training, a signaling indication content being notifying the counterpart of whether to continue training; 6a. the micro base station sends, to the terminal, signaling of a RRC connection releasing request (RRC connection release), a signaling indication content being request for releasing the RRC connection; and 6b. the terminal sends, to the micro base station, signaling of successfully releasing the RRC connection (RRC connection release complete), a signaling indication content being notifying the counterpart that the RRC connection has been successfully released.

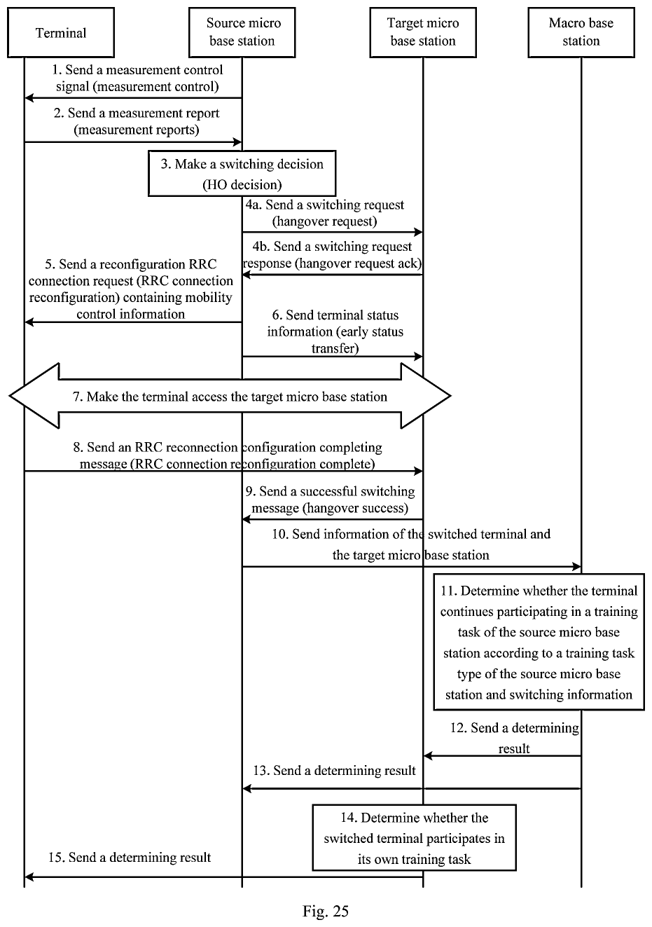

FIG. 25 is a principle diagram of a protocol and an interface for terminal switching in a method for model learning shown according to an example. As shown in FIG. 25, interaction among the macro base station, the source micro base station, the target micro base station and the terminal is mainly involved and is specifically as follows:

1. the source micro base station sends, to the terminal, signaling of sending a measurement control signal (measurement control), a signaling indication content being notifying the counterpart to perform signal intensity measurement; 2. the terminal sends, to the source micro base station, signaling of sending a measurement report (measurement reports), a signaling indication content being sending the measurement report to the receiver; 3. the source micro base station makes a terminal switching decision (HO decision); 4a. the source micro base station sends, to the target micro base station, signaling of sending a switching request (handover request), a signaling indication content being sending the switching request to the receiver; 4b. the target micro base station sends, to the source micro base station, signaling of sending a switching request response (handover request ack), a signaling indication content being sending the switching request response to the receiver; 5. the source micro base station sends, to the terminal, signaling of sending a reconfiguration RRC connection request (RRC connection reconfiguration) containing mobility control information, a signaling indication content being sending the reconfiguration RRC connection request to the receiver; 6. the source micro base station sends, to the target micro base station, signaling of sending terminal status information (early status transfer), a signaling indication content being sending the terminal status information to the receiver; 7. the terminal accesses the target micro base station; 8. the terminal sends, to the target micro base station, signaling of sending an RRC reconnection configuration completing message (RRC connection reconfiguration complete), a signaling indication content being sending the RRC reconnection configuration completing message to the receiver; 9. the target micro base station sends, to the source micro base station, signaling of sending a successful handover message (handover success), a signaling indication content being sending the successful switching message to the receiver; 10. the source micro base station sends, to the macro base station, signaling of sending information of the switched terminal and the target micro base station, a signaling indication content being sending the information of the switched terminal and the target micro base station to the macro base station; 11. the macro base station determines whether the terminal continues participating in the training task of the source micro base station according to the training task type of the source micro base station and the switching information; 12. the macro base station sends, to the target micro base station, signaling of sending a determining result, a signaling indication content being sending the determining result to the receiver; 13. the macro base station sends, to the source micro base station, signaling of sending the determining result, a signaling indication content being sending the determining result to the receiver; 14. the target micro base station determines whether the switched terminal participates in a federated learning training task of the target micro base station; and 15. the target micro base station sends, to the terminal, signaling of sending a determining result, a signaling indication content being sending the determining result to the receiver.

Based on the same concept, an embodiment of the disclosure further provides an apparatus for model learning.

It may be understood that in order to implement the above functions, the apparatus for model learning provided by the embodiment of the disclosure contains corresponding hardware structures and/or software modules for executing each function. In combination with units and algorithm steps of all examples disclosed in the embodiment, the embodiment of the disclosure may be implemented in a form of hardware or a form of combining hardware and computer software. Whether a certain function is executed by the hardware or by driving the hardware through the computer software depends on a specific application and a design constraint condition of a technical solution. Those skilled in the art may implement the described functions for each specific application by using different methods, but this implementation is not regarded as departing from the scope of the technical solution of the embodiment of the disclosure.

In some embodiments of the disclosure, in the apparatus for model learning including one macro base station apparatus, M micro base station apparatuses and N user apparatuses is taken as an example for description.

The user apparatuses are terminals that access the micro base stations, are responsible for local data collection and local model training and may update a local model according to a global model learning result. The micro base station apparatuses are responsible for selecting the terminal that participate in a model training task and a learning mode, performing training task assignment on the terminal that participates in the model training task, gathering local training results of the terminal and performing model alignment and federated averaging by using an AI service module, and meanwhile are responsible for terminal switching management and for forwarding signaling issued by a macro base station to the terminal. The macro base station apparatus is responsible for interacting with an OAM, performs task assignment on the micro base station apparatuses that participate in training, gathers training results of the micro base station apparatuses and performs model alignment and global model learning by using the AI service module, and meanwhile determines whether the terminal continues participating in training when terminal switching occurs.

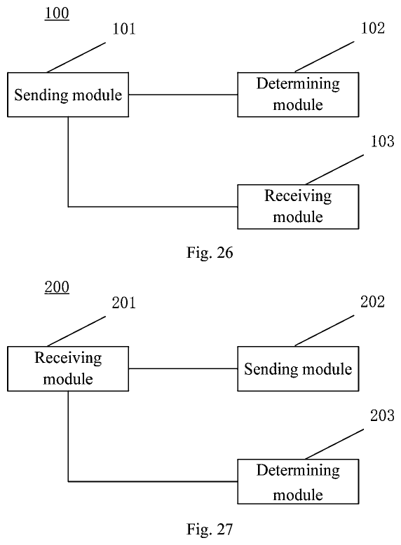

FIG. 26 is a block diagram of an apparatus for model learning shown according to an example. Referring to FIG. 26, the apparatus for model learning 100 is performed by a macro base station and includes a sending module 101, a determining module 102 and a receiving module 103.

The sending module 101 is configured to send a model training request to a first number of micro base stations in response to reception of the model training request sent by an operation administration and maintenance (OAM) entity. A communication coverage range of the first number of micro base stations is within a communication coverage range of the macro base station.

In the embodiment of the disclosure, the model training request is used for triggering the micro base stations to report capability information.

The determining module 102 is configured to determine a model structure and a model parameter value based on the capability information in response to reception of the capability information sent by the micro base stations, and send the model structure and the model parameter value to the micro base stations. The model structure is a model structure that the micro base stations are indicated to train based on the model training request, and the model parameter value is an initial parameter value of the model structure.

In the embodiment of the disclosure, the capability information includes a data type feature of the micro base stations.

The receiving module 103 is configured to receive a first number of first model training results sent by the first number of micro base stations; determine data type features of different micro base stations in the first number of micro base stations, and determine a first model loss function; unify the data type features based on the data type features of the different micro base stations in the first number of micro base stations, and then perform first model alignment on the first number of first model training results with optimizing the first model loss function as an objective; and determine a global model by performing global model learning based on a result of first model alignment.

In the embodiment of the disclosure, the determining module 102 is configured to send a model learning result to the micro base stations in response to a case that the model learning result of global model learning does not meet the model training request of the OAM, and receive the first number of first model training results redetermined by the micro base stations based on the model learning result; redetermine a first model loss function based on the model learning result of global model learning, and re-perform first model alignment on the first number of received first model training results with optimizing the redetermined first model loss function as an objective; and redetermine a model learning result by performing global model learning next time based on the redetermined result of first model alignment till the model learning result meets the model training request, and determine a model corresponding to the model learning result which meets the model training request as a global model.

In the embodiment of the disclosure, the determining module 102 is configured to determine a first loss function between the first number of first model training results of the micro base stations and the model learning result obtained by global model learning last time of the macro base station, and a first model alignment loss function; and determine the first model loss function based on the first loss function and the first model alignment loss function.

In the embodiment of the disclosure, the determining module 102 is configured to send information for stopping model training to the micro base stations in response to a case that a model learning result of global model learning meets the model training request of the OAM, the information for stopping training indicating the micro base stations to stop the terminal from executing the model training task; and determine a model corresponding to the model learning result as the global model, and send the global model to the OAM.

In the embodiment of the disclosure, the determining module 102 is further configured to redetermine a terminal that executes a model training task based on terminal switching information in response to reception of the terminal switching information sent by the micro base stations in a model training process, and send information of the terminal to the micro base stations; the terminal switching information includes information of a terminal that exits model training and a target micro base station that the terminal re-accesses; and the terminal switching information is used for redetermining, by the macro base station, the terminal that executes the model training task.

FIG. 27 is a block diagram of an apparatus for model learning shown according to an example. Referring to FIG. 27, the apparatus for model learning 200 is performed by a micro base station and includes a receiving module 201, a sending module 202 and a determining module 203.

The receiving module 201 is configured to receive a model training request sent by a macro base station. The sending module 202 is configured to send the model training request to a terminal. The number of micro base stations receiving the model training request is a first number. A communication coverage range of the first number of micro base stations is within a communication coverage range of the macro base station.

In the embodiment of the disclosure, the model training request is used for triggering the terminal to report a communication condition and a data type feature of the terminal; and the receiving module 201 is further configured to receive the communication condition and the data type feature sent by the terminal; and obtain capability information by processing the communication condition and the data type feature of the terminal and a communication condition and a data type feature of the micro base stations, and send the capability information to the macro base station. The capability information is used for determining, by the macro base station, a model structure and a model parameter value.

In the embodiment of the disclosure, the receiving module 201 is further configured to receive the model structure and the model parameter value, the model structure being a model structure that the micro base stations are indicated to train based on the model training request, and the model parameter value being an initial parameter value of the model structure; determine a second number of terminals that execute model training based on the communication condition and the data type feature of the terminal, the model structure and the model parameter value; and send scheduling information to the second number of terminals. The scheduling information includes the model structure, the model parameter value as well as indication information for indicating the terminals to perform model training.

In the embodiment of the disclosure, the receiving module 201 is configured to receive a second number of second model training results sent by a second number of terminals. The determining module 203 is configured to determine data type features that different terminals in the second number of terminals have, and determine a second model loss function; unify the data type features based on the data type features that the different terminals in the second number of terminals have, and then perform second model alignment on the second number of second model training results with optimizing the second model loss function as an objective; and obtain a first model training result by performing federated aggregation based on a result of second model alignment.

In the embodiment of the disclosure, the determining module 203 is configured to receive a model learning result sent by the macro base station in response to reception of a continue-to-train request sent by the macro base station; update the model structure and the model parameter value of the terminal based on the model learning result, and send continue-to-train scheduling information to the terminal; redetermine the second model loss function based on the first model training result in response to re-reception of a second number of second model training results, and perform second model alignment on the second number of second model training results with optimizing the redetermined second model loss function as an objective; and redetermine a first model training result by performing federated aggregation next time based on a redetermined result of second model alignment.

In the embodiment of the disclosure, the determining module 203 is configured to determine a second loss function between the second number of second model training results of the terminals and the first model training result obtained by federated aggregation last time of the micro base stations, and a second model alignment loss function; and determine the second model loss function based on the second loss function and the second model alignment loss function.

In the embodiment of the disclosure, the receiving module 201 is further configured to receive information for stopping model training sent by the macro base station, the information for stopping training indicating the micro base stations to stop the terminal from executing the model training task; and indicate, based on the information for stopping model training, the terminal to stop executing the model training task.

In the embodiment of the disclosure, the sending module 202 is further configured to send terminal switching information, the terminal switching information including information of a terminal that exits model training and a target micro base station that the terminal re-accesses, and the terminal switching information being used for redetermining, by the macro base station, the terminal that executes the model training task; and redetermine the terminal that executes the model training task in response to reception of terminal information sent by the macro base station, and send the model training task to the terminal.

In the embodiment of the disclosure, the sending module 202 is configured to determine the target micro base station after terminal switching in response to a case that the terminal information includes the terminal that executes the model training task last time, and send, by the target micro base station, the model training task to the terminal; and/or

determine that the terminal does not execute the model training task any more in response to a case that the terminal information does not include the terminal that executes the model training task last time, determine a newly-added terminal that executes the model training task, and send the model training task to the newly-added terminal that executes the model training task. As for the apparatus in the above embodiments, a specific mode of each module for executing an operation has been described in detail in the embodiment related to the method, which is not described in detail here.

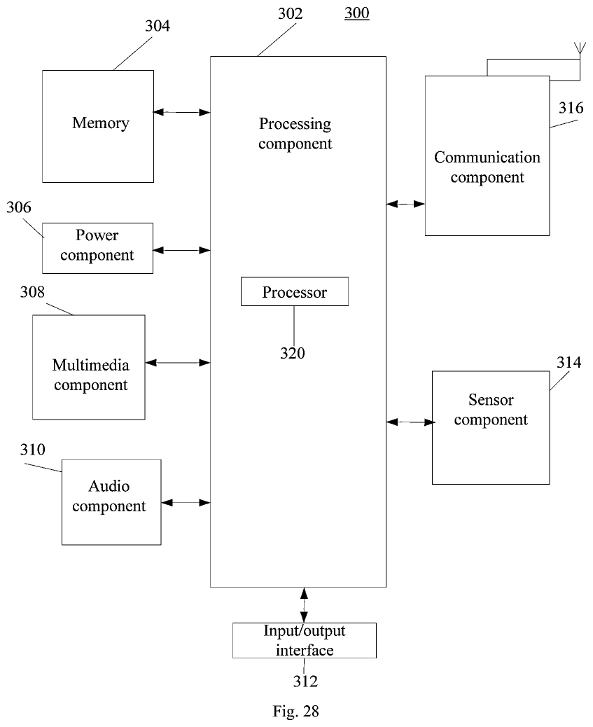

FIG. 28 is a block diagram of an apparatus 300 for model learning shown according to an example. For example, the apparatus 300 may be a mobile phone, a computer, a digital broadcast terminal, a messaging device, a game console, a tablet device, a medical device, a fitness facility, a personal digital assistant and the like.

Referring to FIG. 28, the apparatus 300 may include one or more components as follows: a processing component 302, a memory 304, a power component 306, a multimedia component 308, an audio component 310, an input/output (I/O) interface 312, a sensor component 314 and a communication component 316.

The processing component 302 generally controls whole operation of the apparatus 300, such as operations related to display, phone call, data communication, camera operation and recording operation. The processing component 302 may include one or more processors 320 for executing instructions so as to complete all or part of steps of the above method. Besides, the processing component 302 may include one or more modules to facilitate interaction between the processing component 302 and the other components. For example, the processing component 302 may include a multimedia module so as to facilitate interaction between the multimedia component 308 and the processing component 302.

The memory 304 is configured to store various types of data so as to support operations on the apparatus 300. Examples of these data include instructions of any application program or method for operation on the apparatus 300, contact person data, telephone directory data, messages, pictures, videos and the like. The memory 304 may be implemented by any type of volatile or non-volatile storage device or their combination, such as a static random access memory (SRAM), an electrically erasable programmable read-only memory (EEPROM), an erasable programmable read-only memory (EPROM), a programmable read-only memory (PROM), a read-only memory (ROM), a magnetic memory, a flash memory, a magnetic disk or a compact disc.

The power component 306 provides power for various components of the apparatus 300. The power component 306 may include a power management system, one or more power sources, and other components related to power generation, management and distribution for the apparatus 300.

The multimedia component 308 includes a screen which provides an output interface between the apparatus 300 and a user. In some embodiments, the screen may include a liquid crystal display (LCD) and a touch panel (TP). If the screen includes the touch panel, the screen may be implemented as a touch screen so as to receive an input signal from the user. The touch panel includes one or more touch sensors so as to sense touching, swiping and gestures on the touch panel. The touch sensor can not only sense a boundary of a touching or swiping action, but also detect duration and pressure related to touching or swiping operation. In some embodiments, the multimedia component 308 includes a front camera and/or a back camera. When the apparatus 300 is in an operation mode, such as a photographing mode or a video mode, the front camera and/or the back camera may receive external multimedia data. Each front camera and each back camera may be a fixed optical lens system or have a focal length and an optical zoom capability.

The audio component 310 is configured to output and/or input an audio signal. For example, the audio component 310 includes a microphone (MIC). When the apparatus 300 is in the operation mode, such as a call mode, a recording mode and a voice recognition mode, the microphone is configured to receive an external audio signal. The received audio signal may be further stored in the memory 304 or sent via the communication component 316. In some embodiments, the audio component 310 further includes a speaker for outputting the audio signal.

The I/O interface 312 provides an interface between the processing component 302 and a peripheral interface module, and the above peripheral interface module may be a keyboard, a click wheel, buttons and the like. These buttons may include but are not limited to: a home button, a volume button, a start button and a lock button.

The sensor component 314 includes one or more sensors, configured to provide state evaluation of various aspects for the apparatus 300. For example, the sensor component 314 may detect an on/off state of the apparatus 300 and relative positioning of the components, for example, the components are a display and a keypad of the apparatus 300. The sensor component 314 may further detect location change of the apparatus 300 or one component of the apparatus 300, whether there is contact between the user and the apparatus 300, azimuth or acceleration/deceleration of the apparatus 300 and a temperature change of the apparatus 300. The sensor component 314 may include a proximity sensor, configured to detect existence of a nearby object without any physical contact. The sensor component 314 may further include an optical sensor, such as a CMOS or CCD image sensor, for use in an imaging application. In some embodiments, the sensor component 314 may further include an acceleration sensor, a gyroscope sensor, a magnetic sensor, a pressure sensor or a temperature sensor.

The communication component 316 is configured to facilitate wired or wireless communication between the apparatus 300 and other devices. The apparatus 300 may be accessed to a wireless network based on a communication standard, such as WiFi, 2G or 3G, or their combination. In an example, the communication component 316 receives a broadcast signal or related broadcast information from an external broadcast management system via a broadcast channel. In an example, the communication component 316 further includes a near-field communication (NFC) module so as to promote short-range communication. For example, the NFC module may be implemented based on a radio frequency identification (RFID) technology, an infra-red data association (IrDA) technology, an ultra wide band (UWB) technology, a Bluetooth (BT) technology and other technologies.

In an example, the apparatus 300 may be implemented by one or more application specific integrated circuits (ASICs), digital signal processors (DSPs), digital signal processing devices (DSPDs), programmable logic devices (PLDs), field-programmable gate arrays (FPGAs), controllers, micro control units, microprocessors or other electronic elements for executing the above method.

In an example, a non-transitory computer-readable storage medium including instructions is further provided, such as a memory 304 including the instructions. The above instructions may be executed by a processor 320 of an apparatus 300 so as to complete the above method. For example, the non-transitory computer-readable storage medium may be an ROM, a random access memory (RAM), a CD-ROM, a magnetic tape, a floppy disk, an optical data storage device and the like.

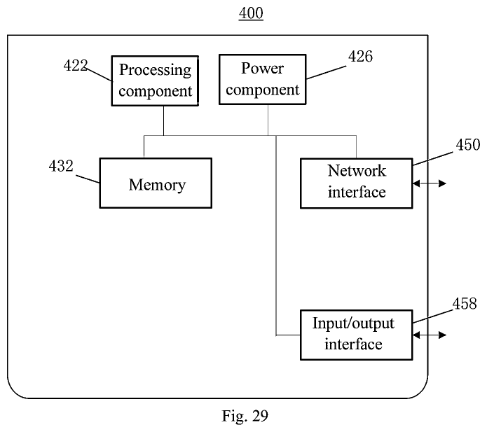

FIG. 29 is a block diagram of an apparatus 400 for model learning shown according to an example. For example, the apparatus 400 may be provided as a server. Referring to FIG. 29, the apparatus 400 includes a processing component 422 which further contains one or more processors and a memory resource represented by a memory 432, configured to store an instruction able to be executed by the processing component 422, for example, an application program. The application program stored in the memory 432 may include one or more modules each of which corresponds to a set of instructions. Besides, the processing component 422 is configured to execute the instructions so as to execute the above method.

The apparatus 400 may also include a power component 426 configured to execute power management of the apparatus 400, a wired or wireless network interface 450 configured to connect the apparatus 400 to a network, and an input/output (I/O) interface 458. The apparatus 400 may operate an operating system stored in the memory 432, for example, Windows Server™, Mac OS X™, Unix™, Linux™, FreeBSD™, or the like.

It may be further understood that “plurality” in the disclosure refers to two or more, and the other quantifiers are similar to this. “And/or” describes an association relationship between associated objects and represents that there may be three relationships, for example, A and/or B, which represents that merely A exists, both A and B exist, and merely B exists. A character “l” generally represents an “or” relationship between associated objects before and after the character. A singular form “a/an”, “the” and “said” intends to include a plural form unless other meanings are indicated clearly in the context.

It may be further understood that terms such as “first” and “second” are used for describing various pieces of information, but these information is not limited by these terms. These terms are merely used for distinguishing the same type of information from one another and do not represent a specific sequence or a significance. Actually, “first”, “second” and the like may be completely interchangeable. For example, without departing from the scope of the disclosure, first information may also be called second information, and similarly, the second information may also be called the first information.

It may be further understood that the operations in the embodiments of the disclosure are described in a specific sequence in the accompanying drawings, but it is not understood as requiring to execute these operations in the specific sequence or a serial sequence as shown, or requiring to execute all the shown operations to achieve an expected result. In a specific environment, multi-task and parallel processing are possibly beneficial.

According to a first aspect of the disclosure, a method for model learning is provided, the method performed by a macro base station, and includes:

sending a model training request to a first number of micro base stations in response to reception of a model training request sent by an operation administration and maintenance (OAM) entity, where a communication coverage range of the first number of micro base stations being within a communication coverage range of the macro base station.

In an implementation, the model training request is used for triggering the micro base stations to report capability information; and after sending the model training request to the first number of micro base stations, the method further includes:

determining a model structure and a model parameter value based on the capability information in response to reception of the capability information sent by the micro base stations, and sending the model structure and the model parameter value to the micro base stations; the model structure being a model structure that the micro base stations are indicated to train based on the model training request, and the model parameter value being an initial parameter value of the model structure.

In an implementation, the capability information includes: a data type feature of the micro base stations; and the method further includes:

receiving a first number of first model training results sent by the first number of micro base stations; determining data type features of different micro base stations in the first number of micro base stations, and determining a first model loss function; unifying the data type features based on the data type features of the different micro base stations in the first number of micro base stations, and then performing first model alignment on the first number of first model training results with optimizing the first model loss function as an objective; and determining a global model by performing global model learning based on a result of first model alignment.

In an implementation, determining the global model by performing global model learning based on the result of first model alignment includes:

sending a model learning result to the micro base stations in response to a case that the model learning result of global model learning does not meet the model training request of the OAM, and receiving the first number of first model training results redetermined by the micro base stations based on the model learning result; redetermining a first model loss function based on the model learning result of global model learning, and re-performing first model alignment on the first number of received first model training results with optimizing the redetermined first model loss function as an objective; and redetermining a model learning result by performing global model learning next time based on the redetermined result of first model alignment till the model learning result meets the model training request, and determining a model corresponding to the model learning result that meets the model training request as the global model.

In an implementation, determining the first model loss function includes:

determining a first loss function between the first number of first model training results of the micro base stations and the model learning result obtained by global model learning last time of the macro base station, and a first model alignment loss function; and determining the first model loss function based on the first loss function and the first model alignment loss function.

In an implementation, determining the global model by performing global model learning based on the result of first model alignment includes:

sending information for stopping model training to the micro base stations in response to a case that a model learning result of global model learning meets the model training request of the OAM, the information for stopping training indicating the micro base stations to stop a terminal from executing a model training task; and determining a model corresponding to the model learning result as a global model, and sending the global model to the OAM.

In an implementation, the method further includes:

redetermining a terminal that executes a model training task based on terminal switching information in response to reception of the terminal switching information sent by the micro base stations in a model training process, and sending information of the terminal to the micro base stations; the terminal switching information including information of a terminal that exits model training and a target micro base station that the terminal re-accesses; and the terminal switching information being used for redetermining, by the macro base station, the terminal that executes the model training task.

According to a second aspect of the disclosure, a method for model learning is provided, the method performed by a micro base station and includes:

receiving a model training request sent by a macro base station; and sending the model training request to a terminal, where the number of micro base stations receiving the model training request is a first number, and a communication coverage range of the first number of micro base stations is within a communication coverage range of the macro base station.

In an implementation, the model training request is used for triggering the terminal to report a communication condition and a data type feature of the terminal; and after sending the model training request to the terminal, the method for model learning further includes:

receiving the communication condition and the data type feature sent by the terminal; and obtaining capability information by processing the communication condition and the data type feature of the terminal and a communication condition and a data type feature of the micro base stations, and sending the capability information to the macro base station, where the capability information is used for determining, by the macro base station, a model structure and a model parameter value.

In an implementation, the method further includes:

receiving the model structure and the model parameter value, the model structure being a model structure that the micro base stations are indicated to train based on the model training request, and the model parameter value being an initial parameter value of the model structure; determining a second number of terminals that execute model training based on the communication condition and the data type feature of the terminal, the model structure and the model parameter value; and sending scheduling information to the second number of terminals, where the scheduling information includes the model structure, the model parameter value as well as indication information for indicating the terminals to perform model training.

In an implementation, the method further includes:

receiving a second number of second model training results sent by a second number of terminals; determining data type features that different terminals in the second number of terminals have, and determining a second model loss function; unifying the data type features based on the data type features that the different terminals in the second number of terminals have, and then performing second model alignment on the second number of second model training results with optimizing the second model loss function as an objective; and obtaining a first model training result by performing federated aggregation based on a result of second model alignment.

In an implementation, obtaining the first model training result by performing federated aggregation based on the result of second model alignment includes:

a model learning result sent by the macro base station is received in response to reception of a continue-to-train request sent by the macro base station; updating the model structure and the model parameter value of the terminal based on the model learning result, and sending continue-to-train scheduling information to the terminal; redetermining the second model loss function based on the first model training result in response to re-reception of the second number of second model training results, and performing second model alignment on the second number of second model training results with optimizing the redetermined second model loss function as an objective; and redetermining a first model training result by performing federated aggregation next time based on a redetermined result of second model alignment.

In an implementation, determining the second model loss function includes:

determining a second loss function between the second number of second model training results of the terminals and the first model training result of the micro base stations obtained by federated aggregation last time, and a second model alignment loss function; and determining the second model loss function based on the second loss function and the second model alignment loss function.

In an implementation, the method further includes:

receiving information for stopping model training sent by the macro base station, the information for stopping training indicating the micro base stations to stop the terminal from executing a model training task; and indicating, based on the information for stopping model training, the terminal to stop executing the model training task.

In an implementation, the method further includes:

sending terminal switching information, the terminal switching information including information of a terminal that exits model training and a target micro base station that the terminal re-accesses, and the terminal switching information being used for redetermining, by the macro base station, a terminal that executes the model training task; and redetermining the terminal that executes the model training task in response to reception of terminal information sent by the macro base station, and sending the model training task to the terminal.

In an implementation, sending the model training task to the terminal includes:

determining the target micro base station to which the terminal is switched in response to a case that the terminal information includes the terminal that executes the model training task last time, and sending, by the target micro base station, the model training task to the terminal; and/or

determining that the terminal does not execute the model training task any more in response to a case that the terminal information does not include the terminal that executes the model training task last time, determining a newly-added terminal that executes the model training task, and sending the model training task to the newly-added terminal that executes the model training task.

According to a third aspect of the disclosure, an apparatus for model learning is provided, the apparatus performed by a macro base station, and includes:

a sending module, configured to send a model training request to a first number of micro base stations in response to reception of a model training request sent by an operation administration and maintenance (OAM) entity, where a communication coverage range of the first number of micro base stations being within a communication coverage range of the macro base station.

In an implementation, the model training request is used for triggering the micro base stations to report capability information; the apparatus further includes: a determining module;

the determining module is configured to determine a model structure and a model parameter value based on the capability information in response to reception of the capability information sent by the micro base stations, and send the model structure and the model parameter value to the micro base stations; and the model structure is a model structure that the micro base stations are indicated to train based on the model training request, and the model parameter value is an initial parameter value of the model structure.

In an implementation, the capability information includes: a data type feature of the micro base stations; the apparatus further includes: a receiving module;

the receiving module is configured to receive a first number of first model training results sent by the first number of micro base stations; determine data type features of different micro base stations in the first number of micro base stations, and determine a first model loss function; unify the data type features based on the data type features of the different micro base stations in the first number of micro base stations, and then perform first model alignment on the first number of first model training results with optimizing the first model loss function as an objective; and determine a global model by performing global model learning based on a result of first model alignment.

In an implementation, the determining module is configured to:

send a model learning result to the micro base stations in response to a case that the model learning result of global model learning does not meet the model training request of the OAM, and receive the first number of first model training results redetermined by the micro base stations based on the model learning result; redetermine a first model loss function based on the model learning result of global model learning, and re-perform first model alignment on the first number of received first model training results with optimizing the redetermined first model loss function as an objective; redetermine a model learning result by performing global model learning next time based on the redetermined result of first model alignment till the model learning result meets the model training request, and determine a model corresponding to the model learning result that meets the model training request as the global model.

In an implementation, the determining module is configured to:

determine a first loss function between the first number of first model training results of the micro base stations and the model learning result obtained by global model learning last time of the macro base station, and a first model alignment loss function; and determine the first model loss function based on the first loss function and the first model alignment loss function.

In an implementation, the determining module is configured to:

send information for stopping model training to the micro base stations in response to a case that a model learning result of global model learning meets the model training request of the OAM, the information for stopping training indicating the micro base stations to stop a terminal from executing a model training task; and determine a model corresponding to the model learning result as a global model, and send the global model to the OAM.

In an implementation, the determining module is further configured to:

redetermine a terminal that executes a model training task based on terminal switching information in response to reception of the terminal switching information sent by the micro base stations in a model training process, and send information of the terminal to the micro base stations; the terminal switching information including information of a terminal that exits model training and a target micro base station that the terminal re-accesses; and the terminal switching information being used for redetermining, by the macro base station, the terminal that executes the model training task.

According to a fourth aspect of the disclosure, an apparatus for model learning is provided, the apparatus performed by a micro base station, and includes:

a receiving module, configured to receive a model training request sent by a macro base station; and a sending module, configured to send the model training request to a terminal; where the number of micro base stations receiving the model training request is a first number; and a communication coverage range of the first number of micro base stations is within a communication coverage range of the macro base station.

In an implementation, the model training request is used for triggering the terminal to report a communication condition and a data type feature of the terminal; and the receiving module is further configured to:
receive the communication condition and the data type feature sent by the terminal; obtain capability information by processing the communication condition and the data type feature of the terminal and a communication condition and a data type feature of the micro base stations, and send the capability information to the macro base station, where the capability information is used for determining, by the macro base station, a model structure and a model parameter value.

In an implementation, the receiving module is further configured to: receive the model structure and the model parameter value, the model structure being a model structure that the micro base stations are indicated to train based on the model training request, and the model parameter value being an initial parameter value of the model structure; determine a second number of terminals that execute model training based on the communication condition and the data type feature of the terminal, the model structure and the model parameter value; and send scheduling information to the second number of terminals, where the scheduling information includes the model structure, the model parameter value as well as indication information for indicating the terminals to perform model training.

In an implementation, the apparatus further includes a determining module;

the receiving module is configured to receive a second number of second model training results sent by a second number of terminals; the determining module is configured to determine data type features that different terminals in the second number of terminals have, and determine a second model loss function; unify the data type features based on the data type features that the different terminals in the second number of terminals have, and then perform second model alignment on the second number of second model training results with optimizing the second model loss function as an objective; and obtain a first model training result by performing federated aggregation based on a result of second model alignment.

In an implementation, the determining module is configured to:

receive a model learning result sent by the macro base station in response to reception of a continue-to-train request sent by the macro base station; update the model structure and the model parameter value of the terminal based on the model learning result, and send continue-to-train scheduling information to the terminal; redetermine the second model loss function based on the first model training result in response to re-reception of a second number of second model training results, and perform second model alignment on the second number of second model training results with optimizing the redetermined second model loss function as an objective; and redetermining a first model training result by performing federated aggregation next time based on a redetermined result of second model alignment.

In an implementation, the determining module is configured to:

determine a second loss function between the second number of second model training results of the terminals and the first model training result of the micro base stations obtained by federated aggregation last time, and a second model alignment loss function; and determine the second model loss function based on the second loss function and the second model alignment loss function.

In an implementation, the receiving module is further configured to receive information for stopping model training sent by the macro base station, the information for stopping training indicating the micro base stations to stop the terminal from executing a model training task; and indicate, based on the information for stopping model training, the terminal to stop executing the model training task.

In an implementation, the sending module is further configured to send terminal switching information, the terminal switching information including information of a terminal that exits model training and a target micro base station that the terminal re-accesses, and the terminal switching information being used for redetermining, by the macro base station, a terminal that executes the model training task; and redetermine the terminal that executes the model training task in response to reception of terminal information sent by the macro base station, and send the model training task to the terminal.

In an implementation, the sending module is configured to:

determine the target micro base station to which the terminal is switched in response to a case that the terminal information includes the terminal that executes the model training task last time, and send, by the target micro base station, the model training task to the terminal; and/or

determine that the terminal does not execute the model training task any more in response to a case that the terminal information does not include the terminal that executes the model training task last time, determine a newly-added terminal that executes the model training task, and send the model training task to the newly-added terminal that executes the model training task.

According to a fifth aspect of the disclosure, an apparatus for model learning is provided, including:

a processor; and a memory configured to store an instruction executable by the processor, the processor being configured to execute the method for model learning in the first aspect or in any implementation of the first aspect or execute the method for model learning in a second aspect or in any implementation of the second aspect.

According to a sixth aspect of an embodiment of the disclosure, a non-transitory computer-readable storage medium is provided, and an instruction in the storage medium, when executed by a processor of a mobile terminal, enables the mobile terminal to execute the method for model learning in the first aspect or in any implementation of the first aspect or execute the method for model learning in a second aspect or in any implementation of the second aspect.

The technical solutions provided by the embodiments of the disclosure may include the following beneficial effects: by sending, by the macro base station, the model training request to the micro base stations, interaction between the macro base station and the micro base station is implemented for performing assignment of the model training task, utilization efficiency of a wireless access network device is improved, channel quality is high, and model reliability, namely, accuracy, is high.

Those skilled in the art will easily figure out other implementation solutions of the disclosure after considering the specification and practicing the disclosure disclosed here. The present disclosure intends to cover any transformation, purpose or adaptive change of the disclosure, these transformations, purposes or adaptive changes conform to a general principle of the disclosure and include common general knowledge or conventional technical means which is not disclosed by the disclosure in the technical field. The specification and the embodiments are merely regarded as examples, and the true scope and spirit of the disclosure are indicated by the following claims.

It is to be understood that the disclosure is not limited to an accurate structure described above and shown in the accompanying drawings, and various modifications and changes may be made without departing from its scope. The scope of the disclosure is limited merely by appended claims.

1. A method for model learning, performed by a macro base station, and comprising:
sending a model training request to a first number of micro base stations on condition that the model training request sent by an operation administration and maintenance (OAM) entity is received,
wherein a communication coverage range of the first number of micro base stations being within a communication coverage range of the macro base station.

2. The method for model learning according to claim 1, wherein the model training request is configured for triggering the micro base stations to report capability information; and the method further comprises:
determining a model structure and a model parameter value based on the capability information on condition that the capability information sent by the micro base stations is received, and sending the model structure and the model parameter value to the micro base stations; and the model structure being a model structure that the micro base stations are indicated to train based on the model training request, and the model parameter value being an initial parameter value of the model structure.

3. The method for model learning according to claim 2, wherein the capability information comprises a data type feature of the micro base stations; and the method further comprises:
receiving a first number of first model training results sent by the first number of micro base stations;
determining data type features of different micro base stations in the first number of micro base stations, and determining a first model loss function;
unifying the data type features based on the data type features of the different micro base stations in the first number of micro base stations, and then performing first model alignment on the first number of first model training results with optimizing the first model loss function as an objective; and
determining a global model by performing global model learning based on a result of first model alignment.

4. The method for model learning according to claim 3, wherein determining the global model by performing global model learning based on the result of first model alignment comprises:
sending a model learning result to the micro base stations on condition that a case that the model learning result of global model learning does not meet the model training request of the OAM entity, and receiving the first number of first model training results redetermined by the micro base stations based on the model learning result;
redetermining a first model loss function based on the model learning result of global model learning, and re-performing first model alignment on the first number of received first model training results with optimizing the redetermined first model loss function as an objective; and
redetermining a model learning result by performing global model learning next time based on the redetermined result of first model alignment until the model learning result meets the model training request, and determining a model corresponding to the model learning result that meets the model training request as the global model.

5. The method for model learning according to claim 4, wherein determining the first model loss function comprises:
determining a first loss function between the first number of first model training results of the micro base stations and the model learning result obtained by global model learning last time of the macro base station, and a first model alignment loss function; and
determining the first model loss function based on the first loss function and the first model alignment loss function.

6. The method for model learning according to claim 3, wherein determining the global model by performing global model learning based on the result of first model alignment comprises:
sending information for stopping model training to the micro base stations on condition that a case that a model learning result of global model learning meets the model training request of the OAM entity, the information for stopping training indicating the micro base stations to stop a terminal from executing a model training task; and
determining a model corresponding to the model learning result as the global model, and sending the global model to the OAM entity.

7. The method for model learning according to claim 1, further comprising:
redetermining a terminal that executes a model training task based on terminal switching information on condition that the terminal switching information sent by the micro base stations in a model training process is received, and sending information of the terminal to the micro base stations;
the terminal switching information comprising information of a terminal that exits model training and a target micro base station that the terminal re-accesses; the terminal switching information being used for redetermining, by the macro base station, the terminal that executes the model training task.

8. A method for model learning, performed by a micro base station, and comprising:
receiving a model training request sent by a macro base station; and
sending the model training request to a terminal, wherein
a number of micro base stations receiving the model training request is a first number; and a communication coverage range of the first number of micro base stations is within a communication coverage range of the macro base station.

9. The method for model learning according to claim 8, wherein the model training request is used for triggering the terminal to report a communication condition and a data type feature of the terminal; and after sending the model training request to the terminal, the method for model learning further comprises:
receiving the communication condition and the data type feature sent by the terminal; and
obtaining capability information by processing the communication condition and the data type feature of the terminal and a communication condition and a data type feature of the micro base stations, and sending the capability information to the macro base station, wherein
the capability information is used for determining, by the macro base station, a model structure and a model parameter value.

10. The method for model learning according to claim 9, further comprising:
receiving the model structure and the model parameter value, the model structure being a model structure that the micro base stations are indicated to train based on the model training request, and the model parameter value being an initial parameter value of the model structure;
determining a second number of terminals that execute model training based on the communication condition and the data type feature of the terminal, the model structure and the model parameter value; and
sending scheduling information to the second number of terminals, wherein the scheduling information comprises the model structure, the model parameter value as well as indication information for indicating the terminals to perform model training.

11. The method for model learning according to claim 10, further comprising:
receiving a second number of second model training results sent by a second number of terminals;
determining data type features that different terminals in the second number of terminals have, and determining a second model loss function;
unifying the data type features based on the data type features that the different terminals in the second number of terminals have, and then performing second model alignment on the second number of second model training results with optimizing the second model loss function as an objective; and
obtaining a first model training result by performing federated aggregation based on a result of second model alignment.

12. The method for model learning according to claim 11, wherein obtaining the first model training result by performing federated aggregation based on the result of second model alignment comprises:
receiving a model learning result sent by the macro base station on condition that a continue-to-train request sent by the macro base station is received;
updating the model structure and the model parameter value of the terminal based on the model learning result, and sending continue-to-train scheduling information to the terminal;
redetermining the second model loss function based on the first model training result on condition that a second number of second model training results is re-received, and performing second model alignment on the second number of second model training results with optimizing the redetermined second model loss function as an objective; and
redetermining a first model training result by performing federated aggregation next time based on a redetermined result of second model alignment.

13. The method for model learning according to claim 12, wherein determining the second model loss function comprises:
determining a second loss function between the second number of second model training results of the terminals and the first model training result of the micro base stations obtained by federated aggregation last time, and a second model alignment loss function; and
determining the second model loss function based on the second loss function and the second model alignment loss function.

14. The method for model learning according to claim 12, further comprising:
receiving information for stopping model training sent by the macro base station, the information for stopping training indicating the micro base stations to stop the terminal from executing a model training task; and
indicating, based on the information for stopping model training, the terminal to stop executing the model training task.

15. The method for model learning according to claim 8, further comprising:
sending terminal switching information, the terminal switching information comprising information of a terminal that exits model training and a target micro base station that the terminal re-accesses, and the terminal switching information being used for redetermining, by the macro base station, a terminal that executes a model training task; and
redetermining the terminal that executes the model training task on condition that terminal information sent by the macro base station is received, and sending the model training task to the terminal.

16. The method for model learning according to claim 15, wherein sending the model training task to the terminal comprises:
determining the target micro base station to which the terminal is switched on condition that a case that the terminal information comprises the terminal that executes the model training task last time, and sending, by the target micro base station, the model training task to the terminal; and/or
determining that the terminal does not execute the model training task any more on condition that a case that the terminal information does not comprise the terminal that executes the model training task last time, determining a newly-added terminal that executes the model training task, and sending the model training task to the newly-added terminal that executes the model training task.

17. (canceled)

18. (canceled)

19. An apparatus for model learning, comprising:
a processor; and
a memory configured to store an instruction executable by the processor,
wherein the processor is configured to:
send a model training request to a first number of micro base stations on condition that the model training request sent by an operation administration and maintenance (OAM) entity is received,
wherein a communication coverage range of the first number of micro base stations being within a communication coverage range of a macro base station.

20. A non-transitory computer-readable storage medium configured to store an instruction that, when executed by a processor of a mobile terminal, enables the mobile terminal to execute the method for model learning according to claim 1.

21. An apparatus for model learning, comprising:
a processor; and
a memory configured to store an instruction executable by the processor,
wherein the processor is configured to load and execute the instructions to implement the method for model learning according to claim 8.

22. A non-transitory computer-readable storage medium configured to store an instruction that, when executed by a processor of a mobile terminal, enables the mobile terminal to execute the method for model learning according to claim 8.
